(19) United States
(12) Patent Application Publication
(10) Pub. No.: US 2026/0065974 A1
(43) Pub. Date: Mar. 5, 2026

(54) ENTROPY BASED DATA LOCATION

(71) Applicant: Rambus Inc., San Jose, CA (US)

(72) Inventors: Dongyun LEE, Sunnyvale, CA (US); Mark D. KELLAM, Siler City, NC (US); Michael Raymond MILLER, Raleigh, NC (US)

(21) Appl. No.: 19/300,833

(22) Filed: Aug. 15, 2025

Related U.S. Application Data
(60) Provisional application No. 63/690,141, filed on Sep. 3, 2024.

(51) Int. Cl. G11C 11/4096; G11C 11/4076; G11C 11/4093

(52) U.S. Cl. CPC G11C 11/4096; G11C 11/4076; G11C 11/4093

(57) ABSTRACT

A fixed size block of data may be compressed, but not reduced in size, resulting in a high entropy (i.e., information carrying) portion and a low entropy (i.e., little or no information carrying—e.g., all zeros) portion. The high entropy portion and the low entropy portion of the compressed block may be stored by a controller in different memory devices of a memory module. The selection of the memory devices on the memory module to store the high entropy portion versus the low entropy portion may be based on temperature indicators associated with the memory devices. When reading or writing data to the module, entropy indicators (e.g., high or low entropy) are communicated and stored on a per memory device basis.

### BRIEF DESCRIPTION OF THE DRAWINGS

FIG. 1 is a block diagram illustrating a memory system.

FIGS. 2A-2E are diagrams illustrating write data location based on data entropy.

FIGS. 3A-3D are diagrams illustrating reading data that was located based on data entropy.

FIG. 4 is a block diagram illustrating a memory system with data entropy based power reduction.

FIGS. 5A-5C are timing diagrams illustrating example communication of entropy indicators.

FIG. 6 is a flowchart illustrating a method of operating a memory system.

FIG. 7 is a flowchart illustrating a method of operating a memory device storing high entropy data.

FIG. 8 is a flowchart illustrating a method of operating a memory device storing low entropy data.

FIG. 9 is a flowchart illustrating a method of operating a controller to write high entropy and low entropy data.

FIG. 10 is a flowchart illustrating a method of operating a controller to read high entropy and low entropy data.

FIG. 11 is a flowchart illustrating a method of operating a controller to locate data based on memory device temperature.

FIG. 12 is a block diagram of a processing system.

### DETAILED DESCRIPTION OF THE EMBODIMENTS

In an embodiment, a fixed size block of data may be compressed, but not reduced in size, resulting in a high entropy (i.e., information carrying) portion and a low entropy (i.e., little or no information carrying—e.g., all zeros) portion. The high entropy portion and the low entropy portion of the compressed block may be stored by a controller in different memory devices of a memory module. In an embodiment, the selection of the memory devices on the memory module to store the high entropy portion versus the low entropy portion may be based on temperature indicators associated with the memory devices. For example, the hotter memory devices of the module, or those subject to degraded thermal conditions (e.g., poor airflow) may be selected to receive low entropy portions of data being written to the module.

In an embodiment, when reading or writing data to the module, entropy indicators (e.g., high or low entropy) are communicated and stored on a per memory device basis. In this manner, devices communicating/storing low entropy data may disable certain internal circuitry to save power. By saving power in this manner, the devices storing/communicating low entropy data generate less heat and thereby improve (i.e., make cooler) the thermal conditions of those devices.

The descriptions and embodiments disclosed herein are made primarily with references to DRAM devices and DRAM memory arrays. This, however, should be understood to be a first example due at least to the widespread adoption of DRAM technology and the sensitivity of DRAM functionality to elevated device temperatures. It should be understood that other memory technologies may also benefit from the methods and/or apparatus described herein. These memory technologies include, but are not limited to static random access memory (SRAM), non-volatile memory (such as flash), conductive bridging random access memory (CBRAM—a.k.a., programmable metallization cell—PMC), resistive random access memory (a.k.a., RRAM or ReRAM), magnetoresistive random-access memory (MRAM), Spin-Torque Transfer (STT-MRAM), phase change memory (PCM), and the like, and/or combinations thereof. Accordingly, it should be understood that in the disclosures and/or descriptions given herein, these aforementioned technologies may be substituted for, included with, and/or encompassed within, the references to DRAM, DRAM devices, and/or DRAM arrays made herein.

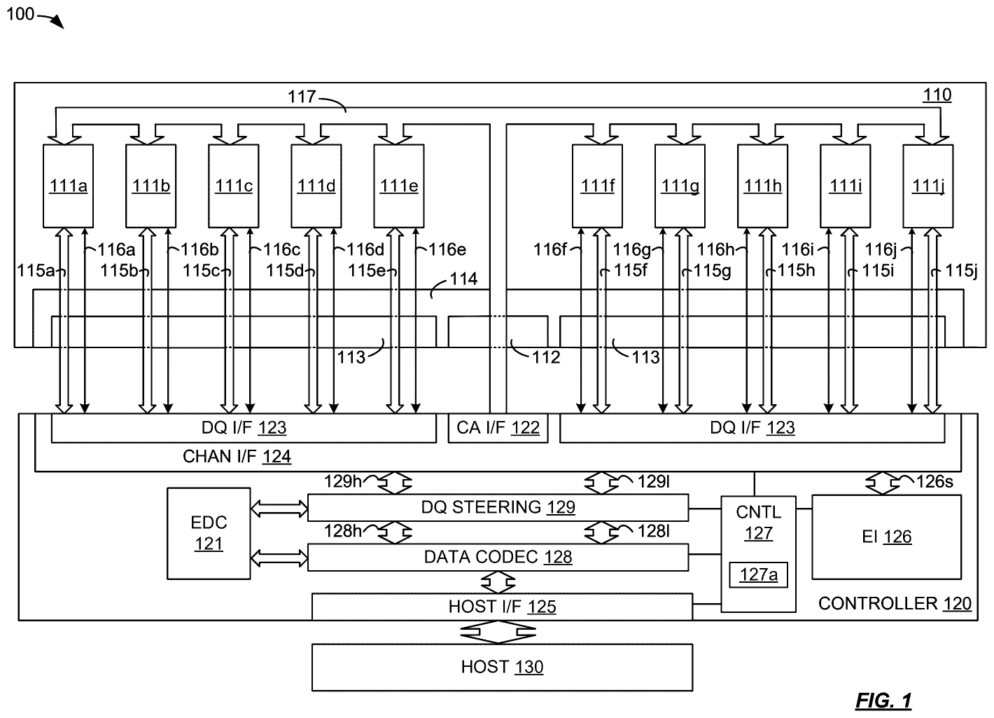

FIG. 1 is a block diagram illustrating a memory system. In FIG. 1, system 100 comprises controller 120, module 110, and host 130. Controller 120 comprises error detection and correction (EDC) circuitry 121, channel interface 124, host interface 125, entropy indicator circuitry 126, control circuitry 127, data compression/decompression (CODEC) circuitry 128, and data (DQ) steering circuitry 129. Control circuitry 127 includes configuration information 127a. Channel interface 124 comprises command/address (CA) interface 122 and data (DQ) interface 123. Module 110 comprises memory devices 111a-111j and channel interface 114. Channel interface 114 comprises CA interface 112 and DQ interface 113.

CA interface 122 of controller 120 (and of channel interface 124) is operatively coupled to CA interface 112 of module 110 (and of channel interface 114). CA interface 122 is operatively coupled to CA interface 112 to communicate CA signals 117 (e.g., commands, row addresses, column addresses, etc.) from controller 120 to memory devices 111a-111j.

Controller 120 is operatively coupled to memory devices 111a-111j of module 110 via DQ interface 123 of channel interface 124 and DQ interface 113 of channel interface 114. Controller 120 and memory devices 111a-111j are operatively coupled via DQ interface 123 and DQ interface 113 to bidirectionally communicate data. Memory devices 111a-111j may store and retrieve data communicated via DQ interface 123 and DQ interface 113. Respective memory devices 111a-111j are operatively coupled with DQ interface 113 (and therefore with DQ interface 123) via respective individual and distinct DQ signal groups 115a-115j (e.g., 4-bit groups, 8-bit groups, etc.) Respective memory devices 111a-111j are also operatively coupled with DQ interface 113 (and therefore with DQ interface 123) via respective individual and distinct timing reference signals (e.g., DQS) 116a-116j that provide timing information for data transfers between respective memory devices 111a-111j via respective DQ signal groups 115a-115j.

Controller 120, memory devices 111a-111j, and host 130 may be or comprise integrated circuit type devices, such as are commonly referred to as a “chips”. The controller functionality of a memory controller (such as the controller functionality of controller 120) manages the flow of data going to and from memory devices and/or memory modules (such as memory module 110). A memory controller can be a separate, standalone chip, or integrated into another chip. For example, a memory controller may be included on a single die with a microprocessor (such as host 130), or included as part of a more complex integrated circuit system such as a block of a system on a chip (SOC). In one or more embodiments, module 110 may be, but is not limited to, a dual inline memory module (DIMM) such as a DDR4, DDR5 etc. DIMM, a load reduced DIMM (LRDIMM), a registered DIMM (RDIMM), a fully buffered DIMM (FB-DIMM), or an unbuffered DIMM (UDIMM).

Host 130 is operatively coupled to controller 120 via host interface 125. Host interface 125 is operatively coupled to data CODEC 128 and control circuitry 127. Data CODEC 128 is operatively coupled to EDC circuitry 121, control circuitry 127 and DQ steering circuitry 129. Data CODEC 128 is operatively coupled to host interface 125 to, under the control of control circuitry 127, receive data blocks to be compressed from host 130. Data blocks received from host 130 may be compressed (if possible) by data CODEC 128 into respective high entropy portions 128h (a.k.a., compressed portion) and a low entropy portions 128l. Data CODEC 128 is operatively coupled to DQ steering circuitry 129 to provide DQ steering circuitry 129 with high entropy portions 128h and low entropy portions 128.

Low entropy portions 128 (a.k.a., a “free” or “empty” portions) corresponds to bits of the original data blocks received from host 130 that are no longer needed to convey the contents of the respective data block received from host 130 because of the compression by data CODEC 128 of the data block into the space occupied by high entropy portion 128h. In some cases, data CODEC 128 may not be able to compress the received data block and therefore the high entropy portion 128h may be the original data block from host 130 and low entropy portion 128l may be empty. In an embodiment, low entropy portion 128l may be, for example, a string of bits that all have the same value (e.g., all 0's or all 1's). In an embodiment, low entropy portion 128l may be communicated by an indicator(s) of which bits, if any, have the same value (e.g., all 0's, all 1's) such as number of least (or most) significant bytes or bits that should be considered by controller 120 to all have that same value. In an embodiment, low entropy portion 128l may be communicated by an indicator(s) of which bits, if any, follow a predefined or configured (e.g., by configuration information 127a) pattern (e.g., alternating 1's and 0's) such as number of least (or most) significant bytes or bits that should be considered by controller 120 to follow the pattern.

Data CODEC 128 is operatively coupled to DQ steering circuitry 129 to, under the control of control circuitry 127, receive high entropy portions 128h and low entropy portions 128l from module 110 via channel interface 124 and DQ steering circuitry 129. High entropy portions 128h and low entropy portions 128l received from module 110 may be decompressed (if possible) by data CODEC 128 into the original data blocks received from host 130.

EDC circuitry 121 is operatively coupled with data CODEC 128 and DQ steering circuitry 129. EDC circuitry 121 is operatively coupled with data CODEC 128 to, under the control of control circuitry 127, generate EDC information (e.g., symbols) from high entropy portion 128h and low entropy portion 128l to be provided to DQ steering circuitry 129 for storage in module 110 in association with high entropy portion 128h and low entropy portion 128l. EDC circuitry 121 is operatively coupled with DQ steering circuitry 129 to, under the control of control circuitry 127, check and correct at least high entropy portion 128h and low entropy portion 128l received from module 110 and provide corrected versions of high entropy portion 128h and low entropy portion 128l to data CODEC 128 for decompression.

DQ steering circuitry 129 is operatively coupled with channel interface 124 (and DQ interface 123, in particular) to arrange, under the control of control circuitry 127, DQ signal group sized portions of high entropy portion 128h and low entropy portion 128l across DQ interface 123 such that the low entropy portions 128l are directed to selected/configured ones of memory devices 111a-111j. The rearranged DQ signal group sized portions of high entropy portions 129h and low entropy portions 129l are provided by DQ steering circuitry 129 to module 110 via channel interface 124. Similarly, and in reverse, rearranged DQ signal group sized portions of high entropy portions 129h and low entropy portions 129l received from module 110 via channel interface 124 are rearranged, under the control of control circuitry 127, back into the original high entropy portions 128h and original low entropy portions 128l by DQ steering circuitry 129 and provided to data CODEC 128 (possibly after being corrected by EDC circuitry 121).

The rearranged DQ signal groups 115a-115j are provided by DQ steering circuitry 129 to channel interface 124 to be transmitted to respective memory devices 111a-111j of module 110 via respective DQ signal groups 115a-115j. In reverse, the rearranged DQ signal groups received via channel interface 124 from respective memory devices 111a-111j of module 110 via respective DQ signal groups 115a-115j are rearranged to reconstitute the original high entropy portions 128h and original low entropy portions 128l by DQ steering circuitry 129.

Entropy indicator circuitry 126 is operatively coupled with channel interface 124 and control circuitry 127. Entropy indicator circuitry 126 is operatively coupled with channel interface 124 to communicate, under the control of control circuitry 127, which, and when, memory devices 111a-111j are communicating high entropy data or low entropy data.

For a write operation, controller 120 may be writing, to each memory device 111a-111j, either high entropy data (e.g., via corresponding DQ signal groups 115a-115j) or low entropy data to each memory device 111a-111j. Entropy indicator circuitry 126 generates entropy indicators 126s associated with each memory device 111a-111j to communicate to each respective memory device 111a-111j whether or not that memory device 111a-111j is receiving (or is to receive) high entropy data to be stored by that memory device 111a-111j. These entropy indicators 126s are communicated via channel interface 124 and channel interface 114 to the respective ones of the memory devices 111a-111j (e.g., via an encoding of timing reference signals 116a-116j). The respective ones of memory device 111a-111j store the respective entropy indicator received in association with the data that is written (e.g., in a metadata field). It should be understood that when data CODEC 128 is unable to compress a data block, each of memory device 111a-111j will be transmitted respective entropy indicators 126s that they are being written high entropy data.

For a read operation, each memory device 111a-111j may be transmitting, to controller 120, either high entropy data (e.g., via corresponding DQ signal groups 115a-115j) or low entropy data. Based on the entropy indicator stored by each of memory devices 111a-111j in association with the data being read, each memory device 111a-111j communicates to controller 120 whether or not that memory device 111a-111j is transmitting (or is to transmit) high entropy data to controller 120. These entropy indicators 126s are communicated via channel interface 114 and channel interface 124 to entropy indicator circuitry 126.

In an embodiment, when a memory device 111a-111j is to store low entropy data according to the entropy indicator transmitted to that memory device 111a-111j, that memory device 111a-111j may disable at least a part of the circuitry typically used during write operations (while still writing and associating a low entropy data indicator with the write data). In this manner, memory devices 111a-111j may reduce, when compared to writing high entropy data, power consumption when writing low entropy data. Similarly, controller 120 may, for memory devices 111a-111j being written low entropy data, only transmit the low entropy data indicator without transmitting the low entropy data via the respective DQ signal group 115a-115j. In this manner, controller 120 may reduce, when compared to writing high entropy data, power consumption when writing low entropy data.

In an embodiment, when a memory device 111a-111j reads low entropy data according to the entropy indicator stored in association with the data being read, that memory device 111a-111j may disable at least a part of the circuitry typically used during read operations (while still transmitting a low entropy data indicator to controller 120). In this manner, memory devices 111a-111j may reduce, when compared to reading high entropy data, power consumption when reading low entropy data. Similarly, controller 120 may, for memory devices 111a-111j that are reading low entropy data, only receive the low entropy data indicator without receiving the low entropy data via the respective DQ signal group 115a-115j. In this manner, controller 120 may reduce, when compared to reading high entropy data, power consumption when reading low entropy data.

In an embodiment, the memory devices 111a-111j that are to receive low entropy data may be statically configured (e.g., by configuration information 127a) by host 130. In another embodiment, the memory devices 111a-111j that are to receive low entropy data may be dynamically configured (e.g., by configuration information 127a—e.g., stored in registers) based on temperature indicators received from memory devices 111a-111j (e.g., via channel interface 114 and channel interface 124, or via a side-channel not shown in FIG. 1). For example, the two hottest memory device 111a-111j may be selected to receive low entropy data (when available). In an embodiment, the memory devices 111a-111j that are to receive low entropy data may be dynamically selected according to a priority scheme. For example, an order based on the temperatures of memory devices 111a-111j may be used to select which memory devices 111a-111j are to receive low entropy data. In other words, when there is only one DQ group width of low entropy data (e.g., 4 bits), the hottest memory device among memory devices 111a-111j is selected to receive the low entropy data, when there are two DQ group widths of low entropy data (e.g., two groups of 4 bits), the hottest two devices are selected, and so on.

In an embodiment, DQ steering circuitry 129 may be configured (e.g., by configuration information 127a) such that DQ groups are circularly shifted right (or left, e.g., configurable) until a first high-entropy DQ group is assigned to a memory device 111a-111j associated with a low temperature memory device 111a-111j (or at least lower temperature than other ones of memory devices 111a-111j) and after that, a first low-entropy DQ group is assigned to a high temperature memory device (or at a higher temperature than other ones of memory devices 111a-111j), shifting right the remaining DQ groups. Other shifting functions and/or algorithms may be used here (e.g., configurable by configuration information 127a) as long as DQ steering circuitry 129 can recover the original order. In an embodiment, DQ steering circuitry 129 may use a static order or shifts set by configuration information 127a.

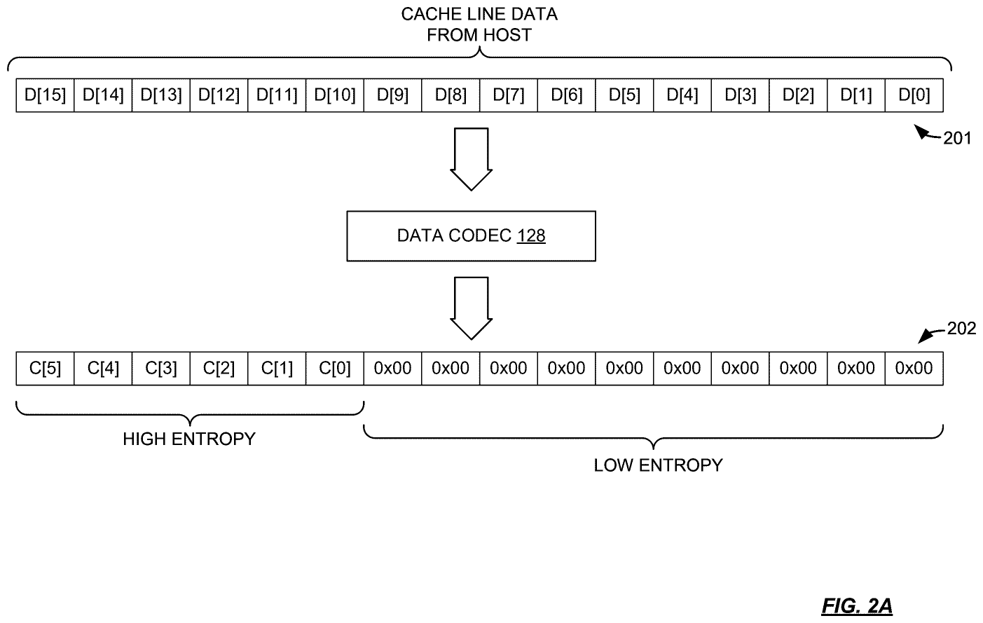

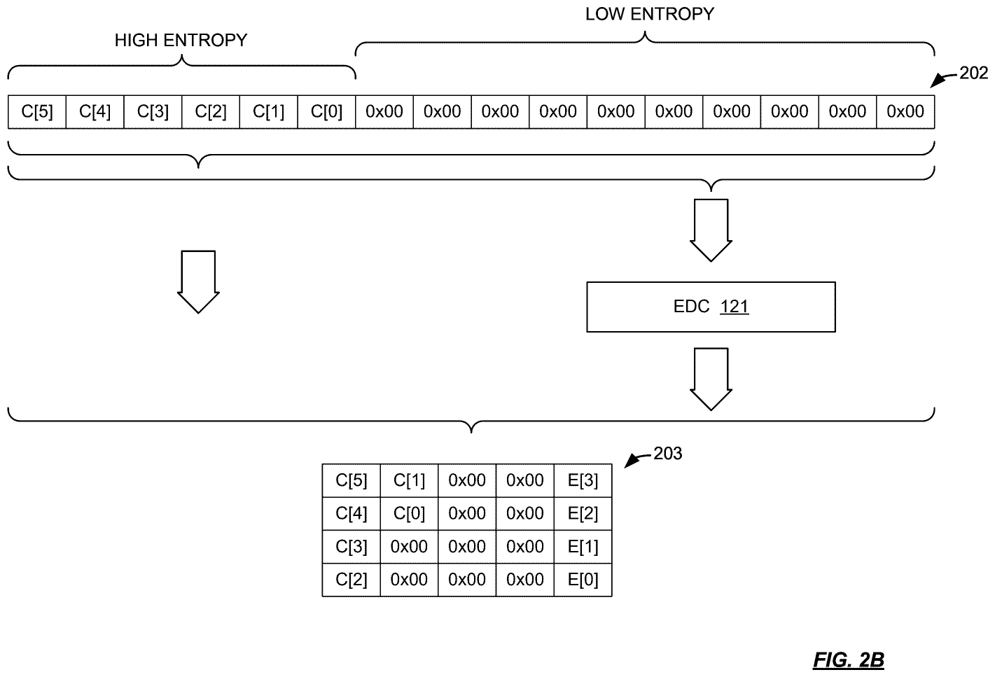

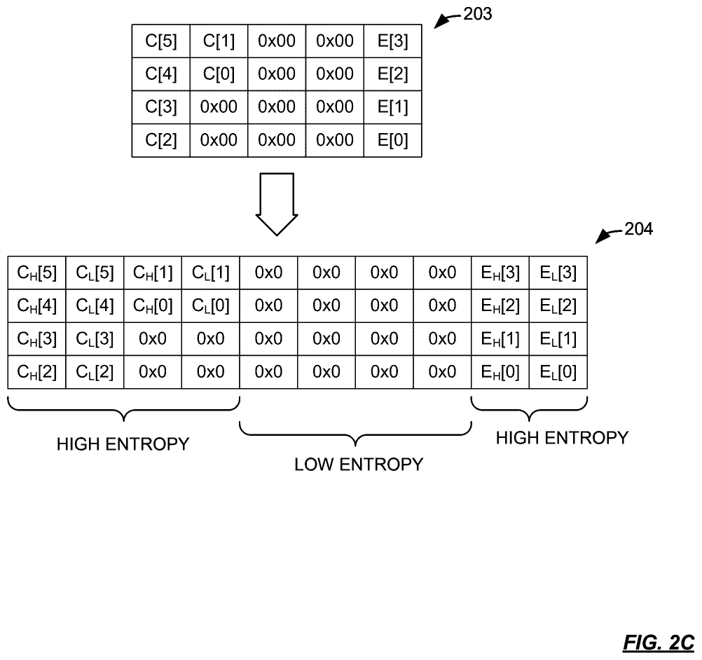

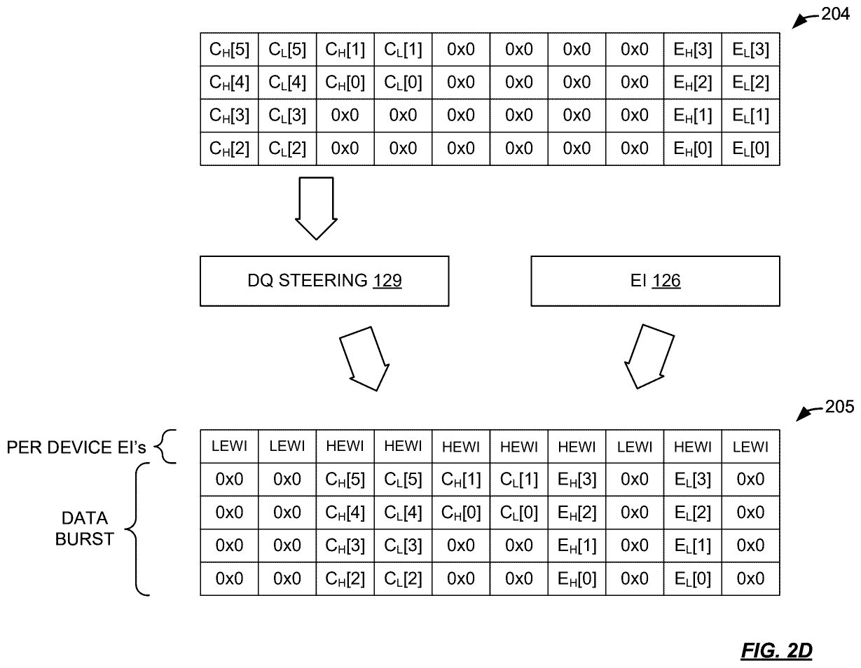

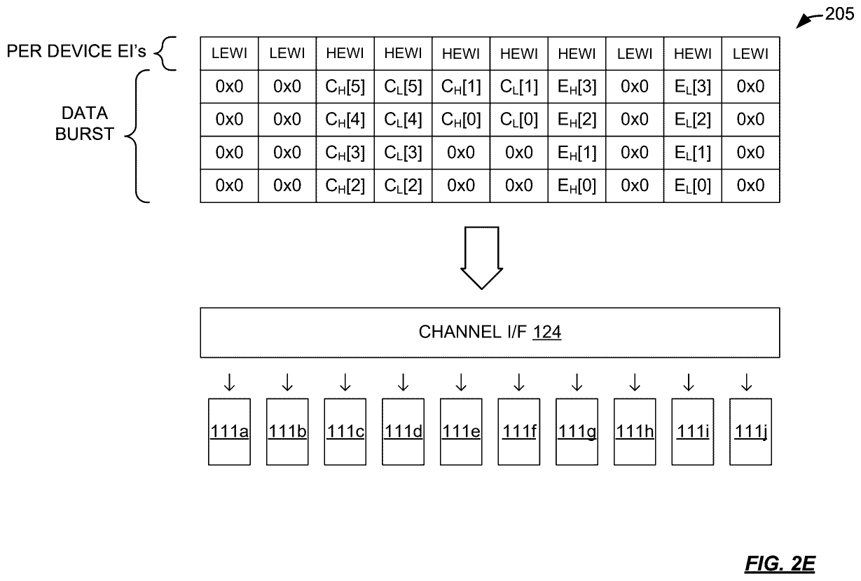

FIGS. 2A-2E are diagrams illustrating write data location based on data entropy. In FIG. 2A, a data block 201 is received from a host (e.g., host 130). Data block 201 is illustrated in FIG. 2A a sixteen bytes D[15:0] of data. The size of data block 201 may correspond to a cache line used by a host. It should be understood that the sixteen byte data block (e.g., cache line size) used as the basis for the elements illustrated in FIGS. 2A-2E is merely one example used for illustration purposes. Other example block sizes (e.g., cache line size) include, but are not limited to 64 byte data blocks (e.g., 64 byte cache line size) and 32 byte data blocks (e.g., 32 byte cache line size) and it is contemplated that the principles illustrated in FIGS. 2A-2E, and associated descriptions, may be extended to those block sizes.

In FIG. 2A, data block 201 is compressed by data CODEC 128 into a compressed data block 202 that comprises a six byte high entropy portion (illustrated as most significant bytes C[5:0]) and a ten byte low entropy portion (ten least significant bytes illustrated in FIG. 2A as having the value 0×00).

In FIG. 2B, compressed data block 202 is processed by error detection and correction circuitry 111 to generate EDC information (illustrated in FIG. 2B as four bytes E[3:0]). The bytes of compressed data block 202 and the EDC information bytes E[3:0] are arranged into a four transfer data burst 203 of 40 bits each. Each byte of data burst 203 includes two 4-bit nibbles. This is illustrated in FIG. 2C by data burst 204 where compressed data bytes C[5:0] are respectively illustrated as a most significant nibble C_{H}[5:0] and least significant nibble C_{L}[5:0], and EDC information bytes are respectively illustrated as a most significant nibble E_{H}[5:0] and least significant nibble E_{L}[5:0].

In FIG. 2D, the nibbles of data burst 204 are rearranged by DQ steering circuitry 129 and entropy indicators generated by entropy indicator circuitry 126. Each entropy indicator is associated with a column of nibbles in data burst 205 with LEWI representing a Low Entropy Write data Indicator and HEWI representing a High Entropy Write data Indicator. Thus, in FIG. 2D, from left to write, the memory devices associated with the first two columns (i.e., columns 1 and 2) of data burst 205 are to receive LEWI indicators (and optionally low entropy data). The memory devices associated with columns 3-7 of data burst 205 are to receive HEWI indicators and high entropy data (i.e., nibbles C_{H}[5:2], C_{L}[5:2], C_{H}[1:0]m C_{L}[1:0], and E_{H}[3:0]). The memory device associated with column 8 of data burst 205 is to receive a LEWI indicator (and optionally low entropy data). The memory device associated with column 9 of data burst 205 is to receive a HEWI indicator and high entropy data (i.e., nibbles E_{L}[3:0]). The memory device associated with column 10 of data burst 205 is to receive a LEWI indicator (and optionally low entropy data).

In an embodiment, DQ steering circuitry 129 may be configured (e.g., by configuration information 127a) such that nibbles are circularly shifted right (or left, e.g., configurable) until a first high-entropy nibble is assigned to a memory device 111a-111j associated with a low temperature memory device 111a-111j (or at least lower temperature than other ones of memory devices 111a-111j) and after that, a first low-entropy nibble is assigned to a high temperature memory device (or at a higher temperature than other ones of memory devices 111a-111j), shifting right the remaining DQ groups. Other shifting functions and/or algorithms may be used here (e.g., configurable by configuration information 127a) as long as DQ steering circuitry 129 can recover the original order. In an embodiment, DQ steering circuitry 129 may use a static order or shifts set by configuration information 127a.

In FIG. 2E, the nibbles in each column of data burst 205, along with the associated entropy indicators are illustrated being provided to channel interface 124 and transmitted to memory devices 111a-111j, respectively. In other words, as illustrated in FIG. 2E, memory device 111a and memory device 111b, via channel interface 124, each receive a LEWI indicator and optionally four transfers of the low entropy data 0×0. Memory device 111c, via channel interface 124, receives a HEWI indicator and high entropy data C_{H}[5:2]. Memory device 111d, via channel interface 124, receives a HEWI indicator and high entropy data C_{L}[5:2]. Memory device 111e, via channel interface 124, receives a HEWI indicator and high entropy data C_{H}[1:0] followed by two 0×0 nibbles. Memory device 111f, via channel interface 124, receives a HEWI indicator and high entropy data C_{L}[1:0] followed by two 0×0 nibbles. Memory device 111g, via channel interface 124, receives a HEWI indicator and high entropy data E_{H}[3:0]. Memory device 111h receives, via channel interface 124, a LEWI indicator and optionally four transfers of the low entropy data 0×0. Memory device 111i, via channel interface 124, receives a HEWI indicator and high entropy data E_{L}[3:0]. Memory device 111h receives, via channel interface 124, a LEWI indicator and optionally four transfers of the low entropy data 0×0.

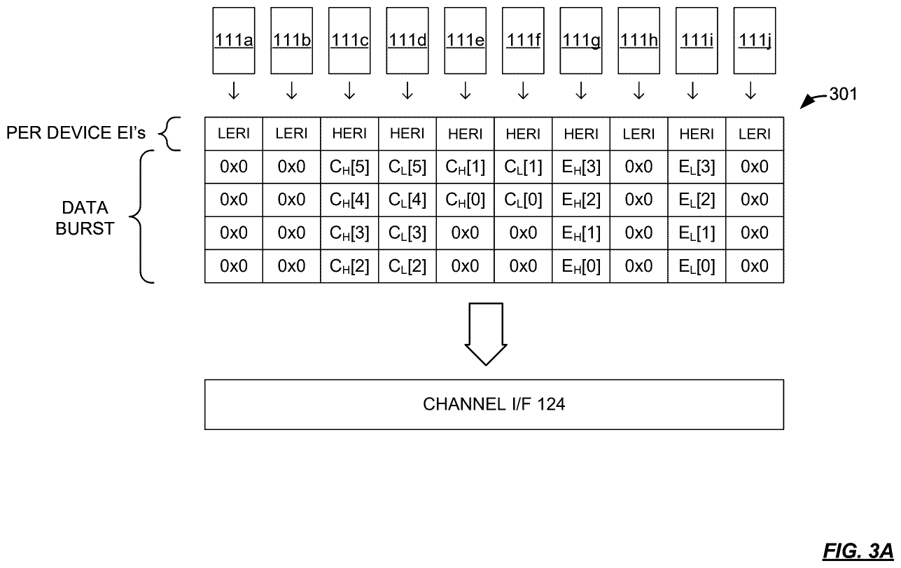

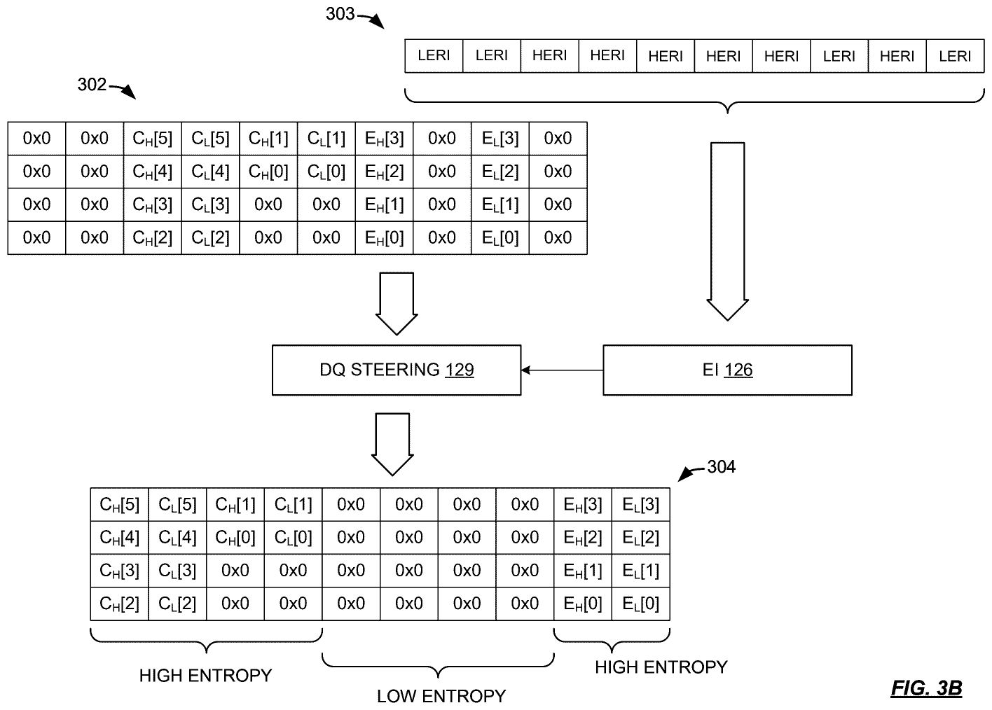

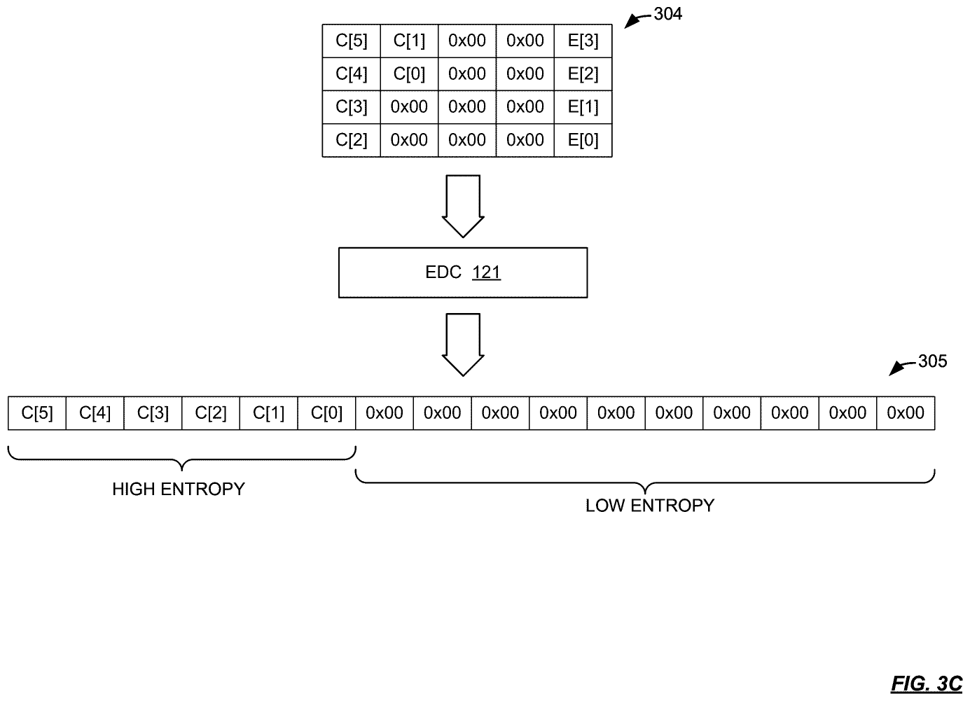

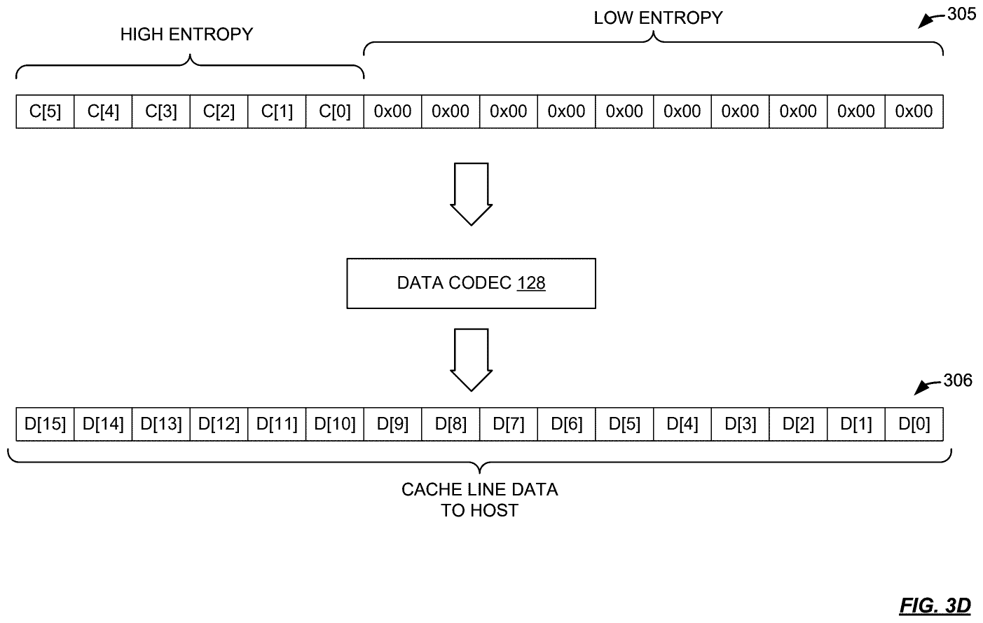

FIGS. 3A-3D are diagrams illustrating reading data that was located based on data entropy. In FIG. 3A, nibbles read from memory devices 111a-111j, along with the associated entropy indicators read from memory devices 111a-111j are respectively illustrated in each column of data burst 301 which is provided to channel interface 124. Each entropy indicator is associated with a column of nibbles in data burst 301 with LERI representing a Low Entropy Read data Indicator and HERI representing a High Entropy Read data Indicator. In FIG. 3B, data burst 302 is provided to DQ steering circuitry 129 and corresponding memory device 111a-111j entropy indicators 303 are provided to entropy indicator circuitry 126. Based on the entropy indicators 303, DQ steering circuitry rearranges the columns of data burst 302 to form data burst 304. In data burst 304, the first four columns (i.e., columns 1-4) have high entropy data C_{H}[5:0] and CL[5:0], the next four columns (i.e., columns 5-8) have the low entropy data 0×00, and the last two columns have high entropy error correction information E_{H}[3:0] and E_{L}[3:0].

In an embodiment, to reverse the shifting (if any) done by DQ steering circuitry 129 when data is stored may be configured (e.g., by configuration information 127a) such that nibbles are shifted left (or right, e.g., configurable) until the leftmost high-entropy nibble is in the leftmost column, and respectively shifting left the remaining nibbles until all of the high-entropy nibbles occupy the corresponding leftmost columns. Other shifting functions and/or algorithms may be used here (e.g., configurable by configuration information 127a) as long as DQ steering circuitry 129 recovers the original order. In an embodiment, DQ steering circuitry 129 may use a static order or shifts set by configuration information 127a to reverse the shifting function used when storing the data.

In FIG. 3C data burst 304 is provided to EDC circuitry 121 for error detection and correction. After possibly being corrected, the data from data burst 304 is arranged into compressed data block 305. Compressed data block 305 that comprises a six byte high entropy portion (illustrated as most significant bytes C[5:0]) and a ten byte low entropy portion (ten least significant bytes illustrated in FIG. 3C as having the value 0×00). In FIG. 3D, compressed data block 305 is provided to data CODEC 128 for decompression into data block 306. Data block 306 is illustrated in FIG. 3D a sixteen bytes D[15:0] of data. Data block 306 may be provided to a host (e.g., host 130).

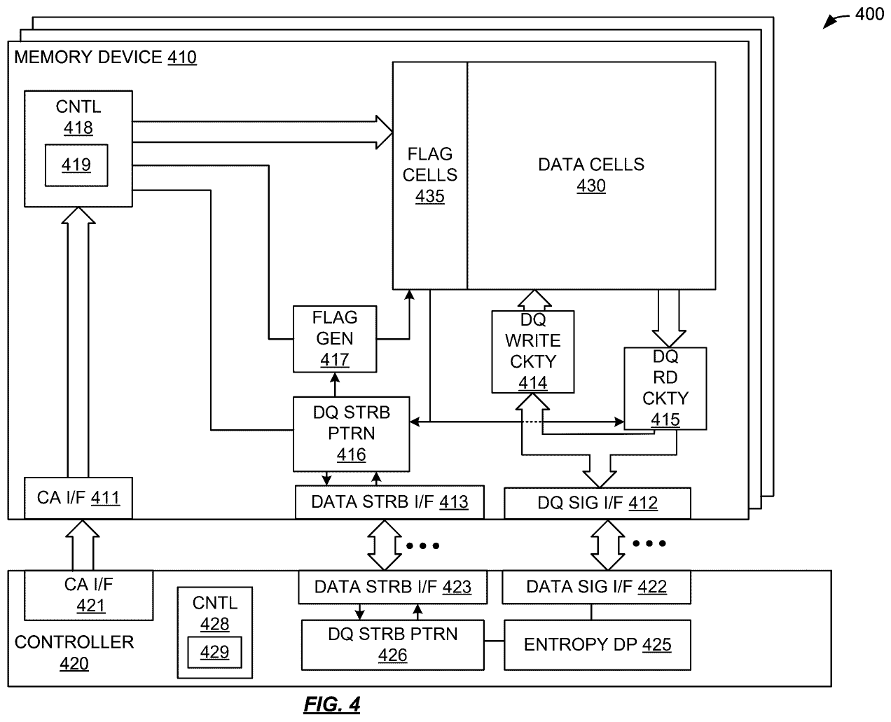

FIG. 4 is a block diagram illustrating a memory system with data entropy based power reduction. In FIG. 4, memory system 400 comprises memory device 410 and memory controller 420. Memory device 410 includes command/address (CA) interface 411, data (DQ) signal interface 412, data strobe (DQS) interface 413, data write circuitry 414, data read circuitry 415, data strobe pattern circuitry 416, flag generation circuitry 417, control circuitry 418, data memory cells 430, and flag memory cells 435. Control circuitry 418 includes configuration information 419 (e.g., registers). Controller 420 includes CA interface 421, DQ signal interface 422, data strobe interface 423, entropy datapath circuitry 425, data strobe pattern circuitry 426, and control circuitry 428. Control circuitry 428 includes configuration information 429 (e.g., registers).

Controller 420 and memory device 410 may be integrated circuit type devices, such as are commonly referred to as “chips”. A memory controller, such as controller 420, manages the flow of data going to and from memory devices and/or memory modules. Memory device 410 may be a standalone device, or may be a component of a memory module such as a DIMM module used in servers. In an embodiment, memory device 410 may be a device that adheres to, or is compatible with, a dynamic random access memory (DRAM) specification. In an embodiment, memory device 410 may be, or comprise, a device that is or includes other memory device technologies and/or specifications. A memory controller can be a separate, standalone chip, or integrated into another chip. For example, a memory controller 420 may be included on a single die with a microprocessor, included as a chip co-packaged with one or more microprocessor chips, included as part of a more complex integrated circuit system such as a block of a system on a chip (SOC), or be remotely coupled to one or more microprocessors via a fabric interconnect or other type of interconnect.

CA interface 421 of controller 420 is operatively coupled to CA interface 411 of memory device 410. CA interface 421 is operatively coupled to CA interface 411 to communicate commands and addresses (e.g., row and column addresses) from controller 420 to memory device 410. Controller 420 is operatively coupled to memory device 410 via DQ signal interface 422 and DQ signal interface 412. Controller 420 is operatively coupled to memory device 410 via data strobe interface 423 and data strobe interface 413. Controller 420 and memory device 410 are operatively coupled via DQ signal interface 422, DQ signal interface 412, data strobe interface 423, and data strobe interface 413 to bidirectionally communicate data and entropy indicators. Memory device 410 may store (e.g., in data memory cells 430) and retrieve (e.g., from data memory cells 430) data communicated via DQ signal interface 422 and DQ signal interface 412. Memory device 410 may store (e.g., in flag memory cells 435) and retrieve (e.g., from flag memory cells 435) entropy indicators communicated via data strobe interface 423, and data strobe interface 413.

CA interface 411 of memory device 410 is operatively coupled to control circuitry 418. Control circuitry 418 is operatively coupled to flag memory cells 435 and data memory cells 430. Control circuitry 418 is also operatively coupled (not shown in FIG. 4) to DQ write circuitry 414 and DQ read circuitry 415. DQ read circuitry 415 may include, but is not limited to, for example, data transmitters (drivers), serializer functions, EDC circuitry, and memory array column circuitry (e.g., sense amplifiers, global buffers, local buffers, row and column decoders, etc.) Control circuitry 418 is also operatively coupled to data strobe pattern circuitry 416 and flag generation circuitry 417. DQ write circuitry 414 may include, but is not limited to, for example, data receivers, deserializer functions, EDC circuitry, and memory array column circuitry (e.g., sense amplifiers, global buffers, local buffers, row and column decoders, etc.) Some elements of DQ write circuitry 414 and DQ read circuitry 415 may overlap (e.g., sense amplifiers, row/column decoders).

Entropy datapath circuitry 425 is operatively coupled with DQ signal interface 422 and data strobe pattern circuitry 426. As described herein with reference to FIG. 1, FIGS. 2A-2E, and FIGS. 3A-3D, entropy datapath circuitry 425 processes data blocks to compress (if possible) these blocks into high entropy portions and low entropy portions. The high entropy portions and low entropy portions are, in DQ signal interface 412 sized groups of bits, rearranged by entropy datapath circuitry 425 to direct the high entropy portion to a first group of memory devices and the low entropy group portion to a second group of memory devices (e.g., based on configuration information 429). Similarly, in reverse, entropy datapath circuitry 425 may, based on high and low entropy read data indicators received from memory device 410 and other memory devices, rearrange data received from (or indicated by) memory device 410 and the other memory device into contiguous high entropy and low entropy portions for decompression. Entropy datapath circuitry 425 may then decompress, if compressed, the rearranged portions to reconstitute the original data blocks.

In an embodiment, when memory device 410 is to receive (e.g., based on a write command transmitted via CA interface 421) high entropy write data (i.e., a DQ signal interface 412 sized group of bits that is part of the high entropy portion of a compressed data block), entropy datapath circuitry 425 directs that write data to the DQ signal interface 422 signals that are coupled to memory device 410. Controller 420 also encodes (e.g., using data strobe pattern circuitry 426) signals to indicate that, based on the write command, memory device 410 is to store high entropy data as opposed to low entropy data. The signals encoded with the high entropy data indicator are transmitted to memory device 410 via data strobe interface 423 and data strobe interface 413. Data strobe pattern circuitry 416 of memory device 410 decodes the signals with the high entropy data indicator and couples the high entropy data indicator to control circuitry 418 and flag generation circuitry 417.

Based on the high entropy data indicator and the write command, memory device 410 (e.g., using control circuitry 418) enables DQ write circuitry 414 to write the high entropy data received via DQ signal interface 412. Also based on the high entropy data indicator and the write command, memory device 410 (e.g., using control circuitry 418) enables flag generation circuitry to write a high entropy data flag to flag memory cells 435 in association with the high entropy data received via DQ signal interface 412.

In an embodiment, when memory device 410 is to receive (e.g., based on a write command transmitted via CA interface 421) low entropy write data (i.e., a DQ signal interface 412 sized group of bits that is part of the low entropy portion of a compressed data block), entropy datapath circuitry 425 may disable or drive a set value via the DQ signal interface 422 signals that are coupled to memory device 410. Controller 420 also encodes (e.g., using data strobe pattern circuitry 426) signals to indicate that, based on the write command, memory device 410 is to store low entropy data as opposed to high entropy data. The signals encoded with the low entropy data indicator are transmitted to memory device 410 via data strobe interface 423 and data strobe interface 413. Data strobe pattern circuitry 416 of memory device 410 decodes the signals with the low entropy data indicator and couples the low entropy data indicator to control circuitry 418 and flag generation circuitry 417.

Based on the low entropy data indicator and the write command, memory device 410 (e.g., using control circuitry 418) disables all or a portion of DQ write circuitry 414 from processing or writing data. For example, based on the low entropy data indicator and the write command, memory device 410 may disable one or more of, or portions of, data receivers, deserializer functions, EDC circuitry, and/or memory array column circuitry of DQ write circuitry 414. Also based on the low entropy data indicator and the write command, memory device 410 (e.g., using control circuitry 418) enables flag generation circuitry to write a low entropy data flag to flag memory cells 435 in association with the location where data would otherwise have been stored based on the write command. It should be understood that the disabling of data write circuitry 414 based on the low entropy data indicator may consume less power than writing low entropy data to data memory cells 430.

In an embodiment, memory device 410, based on the read command, may access at least flag memory cell(s) 435 associated with (e.g., addressed by) the read command. Memory device 410 may access at least a flag memory cell 435 associated with the read command to determine whether the read command was directed to high entropy read data or low entropy read data.

If the accessed flag cell indicates that high entropy read data is associated with the read command, memory device 410 uses DQ read circuitry 415 and DQ signal interface 412 to transmit the high entropy read data obtained from data memory cells 430 to controller 420. Memory device 410 also, based on the accessed flag cell indicating that high entropy read data is associated with the read command, encodes (e.g., using data strobe pattern circuitry 416) signals to indicate that, based on the read command, memory device 410 is to transmit (or is transmitting) high entropy data as opposed to low entropy data. The signals encoded with the high entropy data indicator are transmitted to controller 420 via data strobe interface 413 and data strobe interface 423. Data strobe pattern circuitry 426 of controller 420 decodes the signals with the high entropy data indicator and couples the high entropy data indicator to control circuitry 428 and entropy datapath circuitry 425. As described herein, based on the high entropy data indicator associated with (i.e., from) memory device 410, entropy datapath circuitry 425 of controller 420 may rearrange, and decompress, if compressed, data collectively received from (or indicated by) memory device 410 and other memory devices (e.g., memory devices 111a-111j of module 110).

If the accessed flag cell indicates that low entropy read data is associated with the read command, memory device 410 may disable (e.g., based on configuration information 419) all or a portion of DQ read circuitry 415 and DQ signal interface 412 from transmitting (or otherwise processing, or reading) data from data memory cells 430. For example, based on flag cell indicating that low entropy read data is associated with the read command, memory device 410 may disable one or more of, or portions of, data transmitters, serializer functions, EDC circuitry, and memory array column circuitry of DQ read circuitry 415. Memory device 410 also, based on the accessed flag cell indicating that low entropy read data is associated with the read command, encodes (e.g., using data strobe pattern circuitry 416) signals to indicate that, based on the read command, memory device 410 is indicating low entropy data has been accessed. The signals encoded with the low entropy data indicator are transmitted to controller 420 via data strobe interface 413 and data strobe interface 423. Data strobe pattern circuitry 426 of controller 420 decodes the signals with the low entropy data indicator and couples the low entropy data indicator to control circuitry 428 and entropy datapath circuitry 425. As described herein, based on the low entropy data indicator associated with (i.e., from) memory device 410, entropy datapath circuitry 425 of controller 420 may rearrange and decompress, if compressed, data collectively received from (or indicated by) memory device 410 and other memory devices (e.g., memory devices 111a-111j of module 110).

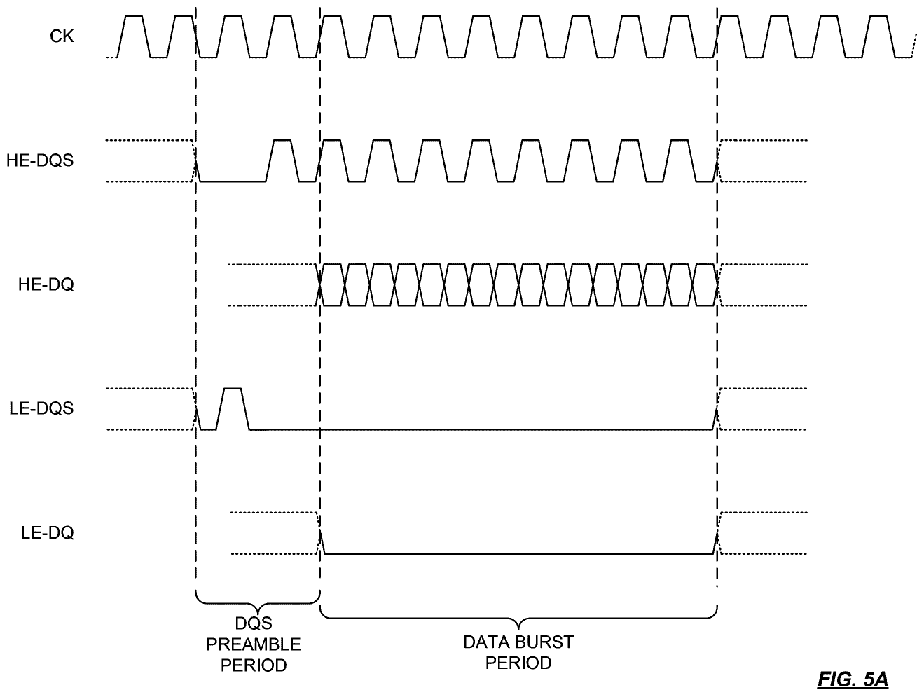

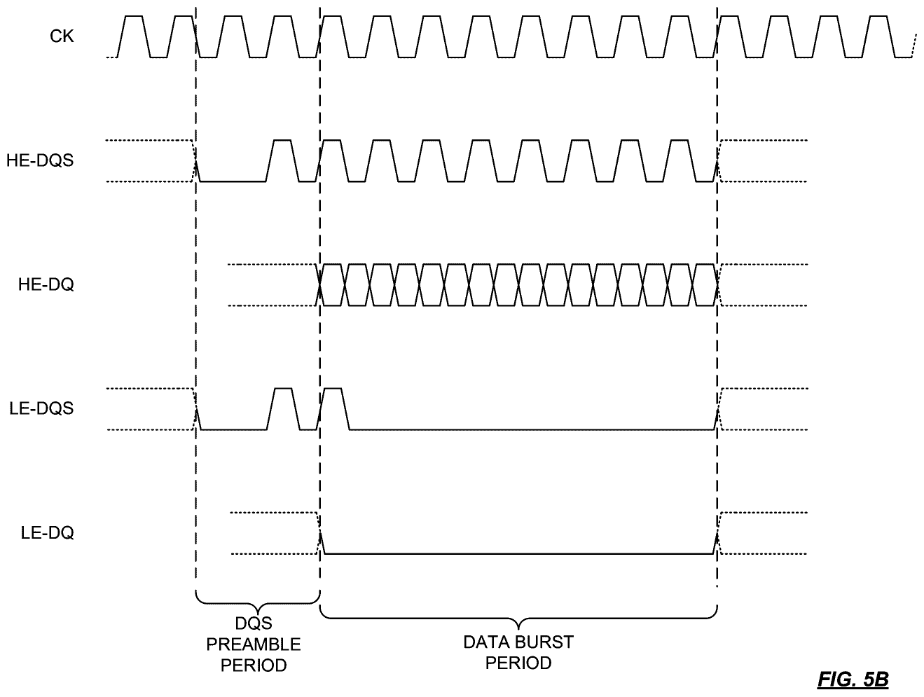

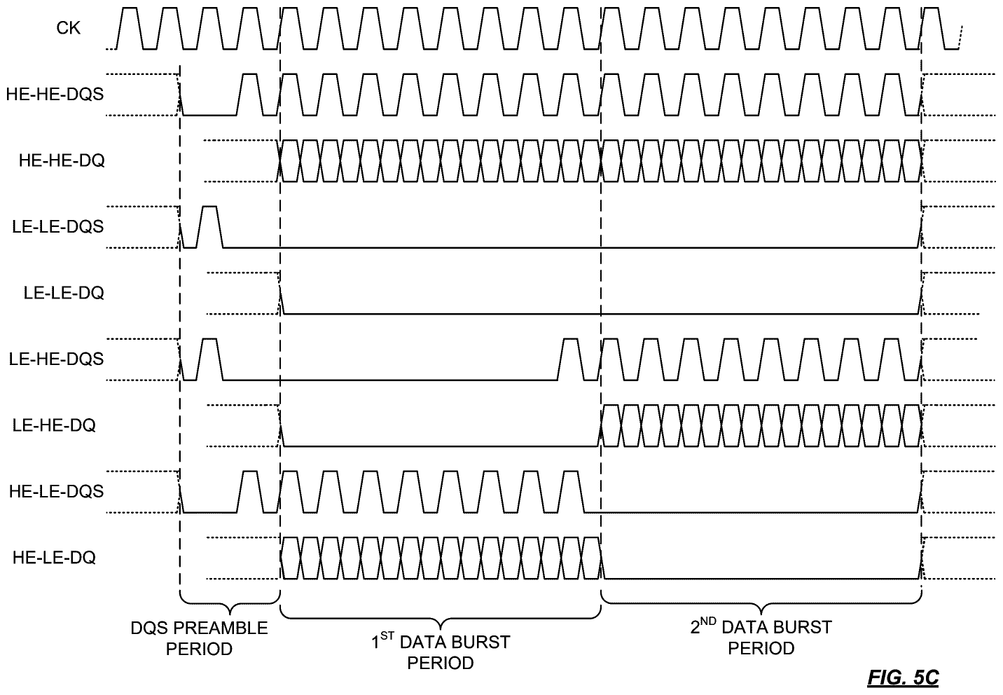

FIGS. 5A-5C are timing diagrams illustrating example communication of entropy indicators. FIG. 5A is a first example diagram illustrating example communication, using data strobe signals, of high and low entropy read and write data indicators. In FIG. 5A, a data strobe preamble time period and a data burst time period are illustrated. To communicate high entropy data (represented in FIG. 5A by the signal HE-DQ), a high entropy data strobe pattern is transmitted (e.g., on a DQS signal by data strobe interface 413 and/or data strobe interface 423). The high entropy data strobe pattern is illustrated in FIG. 5A by the switching pattern HE-DQS. In FIG. 5A, the HE-DQS pattern starts at the beginning of the preamble period as a logical “low” for three clock (CK) phases, then a logical “high” for one CK phase, then a logical low for one clock phase at the end of which the end of the preamble period is indicated by the transition to a logical high. This preamble indicates that high entropy data is being transmitted (e.g., by memory device 410 and/or controller 420). During the data burst period, the pattern HE-DQS starts as a logical high, then toggles between high and low states for 16 clock phases, after which the end of the data burst period is indicated. Also during the data burst period, high entropy data signals HE-DQ are illustrated switching states as timed by the edges (low-to-high and high-to-low) of the HE-DQS pattern.

To communicate or indicate low entropy data (represented in FIG. 5A by the signal LE-DQ), a low entropy data strobe pattern is transmitted (e.g., on a DQS signal by data strobe interface 413 and/or data strobe interface 423). The low entropy data strobe pattern is illustrated in FIG. 5A by the switching pattern LE-DQS. In FIG. 5A, the LE-DQS pattern starts at the beginning of the preamble period as a logical low for one clock (CK) phase, then a logical high for one CK phase, then a logical low for three clock phase at the end of which the preamble period ends (as timed by the CK signal). This preamble indicates that low entropy data is being indicated (e.g., by memory device 410 and/or controller 420). In FIG. 5A, during the data burst period, the pattern LE-DQS remains at the same state (i.e., low). Also in FIG. 5A, during the data burst period, low entropy data signals LE-DQ are illustrated not switching states.

FIG. 5B is a second example diagram illustrating example communication, using data strobe signals, of high and low entropy read and write data indicators. In FIG. 5B, a data strobe preamble time period and a data burst time period are illustrated. To communicate high entropy data (represented in FIG. 5B by the signal HE-DQ), a high entropy data strobe pattern is transmitted (e.g., on a DQS signal by data strobe interface 413 and/or data strobe interface 423). The high entropy data strobe pattern is illustrated in FIG. 5B by the switching pattern HE-DQS. In FIG. 5B, the HE-DQS pattern starts at the beginning of the preamble period as a logical “low” for three clock (CK) phases, then a logical “high” for one CK phase, then a logical low for one clock phase at the end of which the end of the preamble period is indicated by the transition to a logical high. During the data burst period, the pattern HE-DQS starts as a logical high, then toggles between high and low states for 16 clock phases, after which the end of the data burst period is indicated. This DQS pattern during the data burst period indicates that high entropy data is being transmitted (e.g., by memory device 410 and/or controller 420). Also during the data burst period, high entropy data signals HE-DQ are illustrated switching states as timed by the edges (low-to-high and high-to-low) of the HE-DQS pattern.

To communicate or indicate low entropy data (represented in FIG. 5B by the signal LE-DQ), a low entropy data strobe pattern is transmitted (e.g., on a DQS signal by data strobe interface 413 and/or data strobe interface 423). The low entropy data strobe pattern is illustrated in FIG. 5B by the switching pattern LE-DQS. In FIG. 5B, the LE-DQS pattern starts at the beginning of the preamble period as a logical low for three clock (CK) phases, then a logical high for one CK phase, then a logical low for one clock phase at the end of which the preamble period ends (as timed by the CK signal). In FIG. 5B, during the data burst period, the pattern LE-DQS goes high for one phase, then goes low and remains at the same state (i.e., low) for the remainder of the data burst period. This DQS pattern during the data burst period indicates that low entropy data is being indicated (e.g., by memory device 410 and/or controller 420). Also in FIG. 5B, during the data burst period, low entropy data signals LE-DQ are illustrated not switching states.

FIG. 5C is an example diagram illustrating example communication, using data strobe signals, of high and low entropy read and write data indicators for successive data bursts. In FIG. 5C, a data strobe preamble time period, a first data burst time period, and a successive second data burst period are illustrated. To communicate a high entropy data burst followed by another high entropy data burst (represented in FIG. 5C by the signal HE-HE-DQ), a high entropy data strobe pattern is transmitted for the preamble period, the first data burst time period, and the second data burst period (e.g., on a DQS signal by data strobe interface 413 and/or data strobe interface 423). The data strobe pattern for high entropy data followed by high entropy data is illustrated in FIG. 5C by the switching pattern HE-HE-DQS. In FIG. 5C, the HE-HE-DQS pattern starts at the beginning of the preamble period as a logical “low” for three clock (CK) phases, then a logical “high” for one CK phase, then a logical low for one clock phase at the end of which the end of the preamble period is indicated by the transition to a logical high. This preamble indicates that high entropy data is being transmitted in the first data burst period (e.g., by memory device 410 and/or controller 420). During the first data burst period, the pattern HE-HE-DQS starts as a logical high, then toggles between high and low states for 16 clock phases, after which the end of the first data burst period is indicated. Also during the first data burst period, data signals HE-HE-DQ are illustrated switching states as timed by the edges (low-to-high and high-to-low) of the HE-HE-DQS pattern. During the second data burst period, the pattern HE-HE-DQS continues to toggle between high and low states for another 16 clock phases, after which the end of the second data burst period is indicated. Also during the second data burst period, data signals HE-HE-DQ are illustrated switching states as timed by the edges (low-to-high and high-to-low) of the HE-HE-DQS pattern.

To communicate or indicate a low entropy data burst followed by another low entropy data burst (represented in FIG. 5C by the signal LE-LE-DQ), a low entropy data strobe pattern is transmitted during the preamble period, the first data burst time period, and the second data burst period (e.g., on a DQS signal by data strobe interface 413 and/or data strobe interface 423). The data strobe pattern for low entropy data followed by low entropy data is illustrated in FIG. 5C by the switching pattern LE-LE-DQS. In FIG. 5C, the LE-LE-DQS pattern starts at the beginning of the preamble period as a logical low for one clock (CK) phase, then a logical high for one CK phase, then a logical low for three clock phase at the end of which the preamble period ends (as timed by the CK signal). This preamble indicates that low entropy data is being indicated for the first data burst period (e.g., by memory device 410 and/or controller 420). In FIG. 5C, during the first data burst period and the second data burst period, the pattern LE-LE-DQS remains at the same state (i.e., low). Also in FIG. 5C, during the first data burst period and the second data burst period, data signals LE-LE-DQ are illustrated not switching states.

To communicate or indicate a low entropy data burst followed by a high entropy data burst (represented in FIG. 5C by the signal LE-HE-DQ), a low entropy data strobe pattern is transmitted during the preamble period (e.g., on a DQS signal by data strobe interface 413 and/or data strobe interface 423). The data strobe pattern for low entropy data followed by high entropy data is illustrated in FIG. 5C by the switching pattern LE-HE-DQS. In FIG. 5C, the LE-HE-DQS pattern starts at the beginning of the preamble period as a logical low for one clock (CK) phase, then a logical high for one CK phase, then a logical low for three clock phase at the end of which the preamble period ends (as timed by the CK signal). This preamble indicates that low entropy data is being indicated for the first data burst period (e.g., by memory device 410 and/or controller 420).

In FIG. 5C, during the first data burst period, the pattern LE-HE-DQS remains at the same state (i.e., low) until two clock phases before the end of the first data burst period. In FIG. 5C, the LE-HE-DQS pattern goes to a logical high for one clock phase during the second to last phase of the first data burst period, then returns to a logical low for the last phase of the first data burst period. This switching pattern for the last two phases of the first data burst period indicates that high entropy data is being indicated for the second data burst period (e.g., by memory device 410 and/or controller 420) Also in FIG. 5C, during the first data burst period, data signals LE-HE-DQ are illustrated not switching states. During the second data burst period, the pattern LE-HE-DQS starts as a logical high, then toggles between high and low states for 16 clock phases, after which the end of the second data burst period is indicated. Also during the second data burst period, data signals LE-HE-DQ are illustrated switching states as timed by the edges (low-to-high and high-to-low) of the LE-HE-DQS pattern.

To communicate or indicate a high entropy data burst followed by a low entropy data burst (represented in FIG. 5C by the signal HE-LE-DQ), a high entropy data strobe pattern is transmitted during the preamble period (e.g., on a DQS signal by data strobe interface 413 and/or data strobe interface 423). The data strobe pattern for high entropy data followed by low entropy data is illustrated in FIG. 5C by the switching pattern HE-LE-DQS. In FIG. 5C, the HE-LE-DQS pattern starts at the beginning of the preamble period as a logical “low” for three clock (CK) phases, then a logical “high” for one CK phase, then a logical low for one clock phase at the end of which the end of the preamble period is indicated by the transition to a logical high. This preamble indicates that high entropy data is being transmitted in the first data burst period (e.g., by memory device 410 and/or controller 420). During the first data burst period, the pattern HE-LE-DQS starts as a logical high, then toggles between high and low states for 16 clock phases, after which the end of the first data burst period is indicated. Also during the first data burst period, data signals HE-LE-DQ are illustrated switching states as timed by the edges (low-to-high and high-to-low) of the HE-LE-DQS pattern. In FIG. 5C, during the second data burst period, the pattern HE-LE-DQS remains at the same state (i.e., low). Also in FIG. 5C, during the second data burst period, data signals HE-LE-DQ are illustrated not switching states.

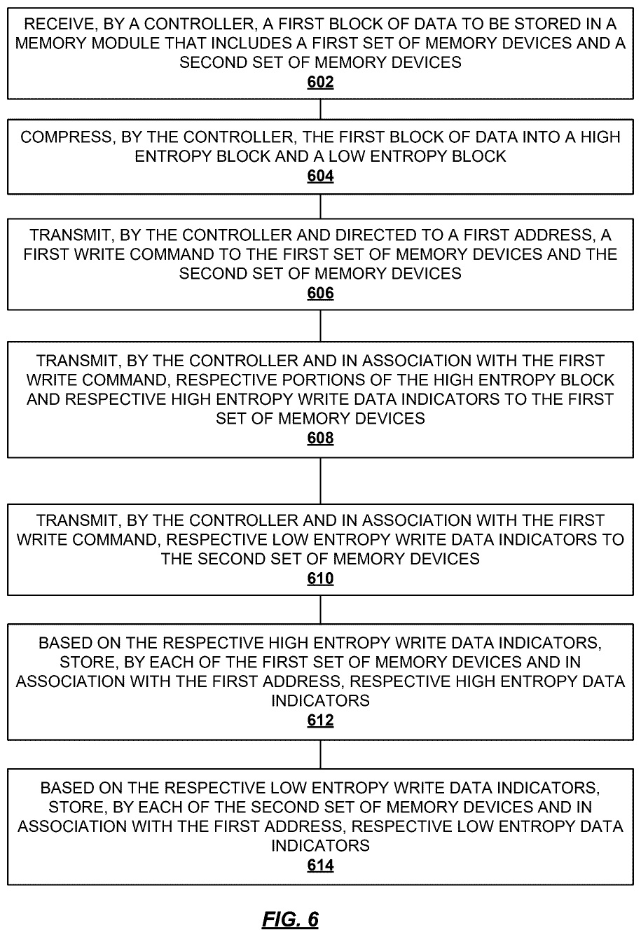

FIG. 6 is a flowchart illustrating a method of operating a memory system. The steps illustrated in FIG. 6 may be performed by one or more elements of system 100, and/or system 400. By a controller, a first block of data to be stored in a memory module that includes a first set of memory devices and a second set of memory devices is received (602). For example, controller 120 may receive, from host 130, a cache line sized data block to be stored in module 110, which includes a first set of memory devices (e.g., memory device 111a, memory device 111b, memory device 111h, and memory device 111j that controller 120 is configured to direct low entropy data to) and a second set of memory devices (e.g., memory devices 111c-111g, and memory device 111i that controller 120 is configured to direct high entropy data to).

By the controller, the first block of data is compressed into a high entropy block and a low entropy block (604). For example, controller 120, using data CODEC 128, may compress the data block from host 130 into a high entropy portion 128h and a low entropy portion 128l. By the controller and directed to a first address, a first write command is transmitted to the first set of memory devices and the second set of memory devices (606). For example, controller 120 may transmit, using CA interface 122, a write command, directed to a first address, to memory devices 111a-111j of module 110.

By the controller and in association with the first write command, respective portions of the high entropy block and respective high entropy indicators are transmitted to the first set of memory devices (608). For example, controller 120 may transmit, to each of memory devices 111c-111g, and memory device 111i, high entropy data indicators (e.g., using encoded per memory device data strobe signals—e.g., a normal preamble pattern) and corresponding portions of the high entropy portion 128h of the compressed data block generated by data CODEC 128. By the controller and in association with the first write command, respective low entropy write data indicators are transmitted to the second set of memory devices (610). For example, controller 120 may transmit, to each of memory device 111a, memory device 111b, memory device 111h, and memory device 111j, low entropy write data indicators (e.g., using encoded per memory device data strobe signals).

Based on the respective high entropy write data indicators, by each of the first set of memory devices, and in association with the first address, respective high entropy data indicators are stored (612). For example, based on the high entropy write data indicators received by each of memory devices 111c-111g, and memory device 111i, each of memory devices 111c-111g, and memory device 111i may store, in association with the first address, an indicator (e.g., a flag) that the first address is associated with high entropy data. Based on the respective low entropy write data indicators, by each of the second set of memory devices, and in association with the first address, respective low entropy data indicators are stored (614). For example, based on the low entropy write data indicators received by each of memory device 111a, memory device 111b, memory device 111h, and memory device 111j, each of memory device 111a, memory device 111b, memory device 111h, and memory device 111j may store, in association with the first address, an indicator (e.g., a flag) that the first address is associated with low entropy data.

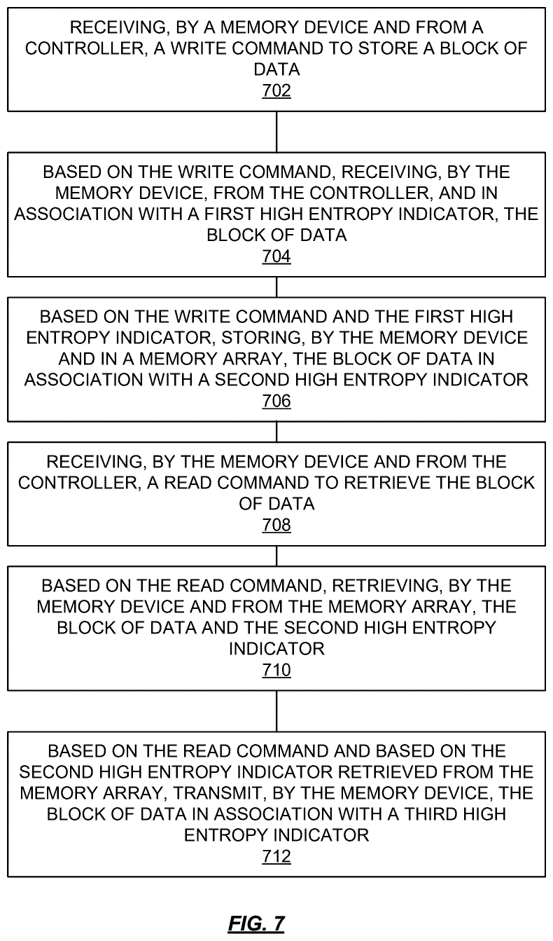

FIG. 7 is a flowchart illustrating a method of operating a memory device storing high entropy data. The steps illustrated in FIG. 7 may be performed by one or more elements of system 100, and/or system 400. By a memory device and from a controller, a write command to store a block of data is received (702). For example, memory device 410 may receive, from controller 420, a write command to store a data burst of data.

Based on the write command, by the memory device, from the controller, and in association with a first high entropy indicator, the block of data is received (704). For example, memory device 410 may receive, from controller 420, the write data for the write command in association with a data strobe pattern (e.g., HE-DQS pattern illustrated in FIG. 5A and FIG. 5B) that indicates high entropy data is being transmitted. Based on the write command, the first high entropy indicator, in a memory array, and by the memory device, the block of data is stored in association with a second high entropy indicator (706). For example, based on the write command and based on the data strobe pattern that indicates high entropy write data is being transmitted, the write data may be stored by memory device 410 in data memory cells 430 in association with a high entropy indicator in flag memory cells 435.

By a memory device and from a controller, a read command to retrieve a block of data is received (708). For example, memory device 410 may receive, from controller 420, a read command to retrieve from data memory cells 430 a data burst of data. Based on the read command, by the memory device, and from the memory array, the block of data and the second high entropy indicator are retrieved (710). For example, memory device 410 may, based on the read command, retrieve a block of data from data memory cells 430 and an associated high entropy indicator from flag memory cells 435.

Based on the read command, the second high entropy indicator retrieved from the memory array, and by the memory device, the block of data is transmitted in association with a third high entropy indicator (712). For example, based on the read command and the high entropy indicator retrieved from flag memory cells 435, memory device 410 may transmit the block of data from data memory cells 430 in association with a data strobe pattern (e.g., HE-DQS pattern illustrated in FIG. 5A and FIG. 5B) that indicates high entropy data is being transmitted.

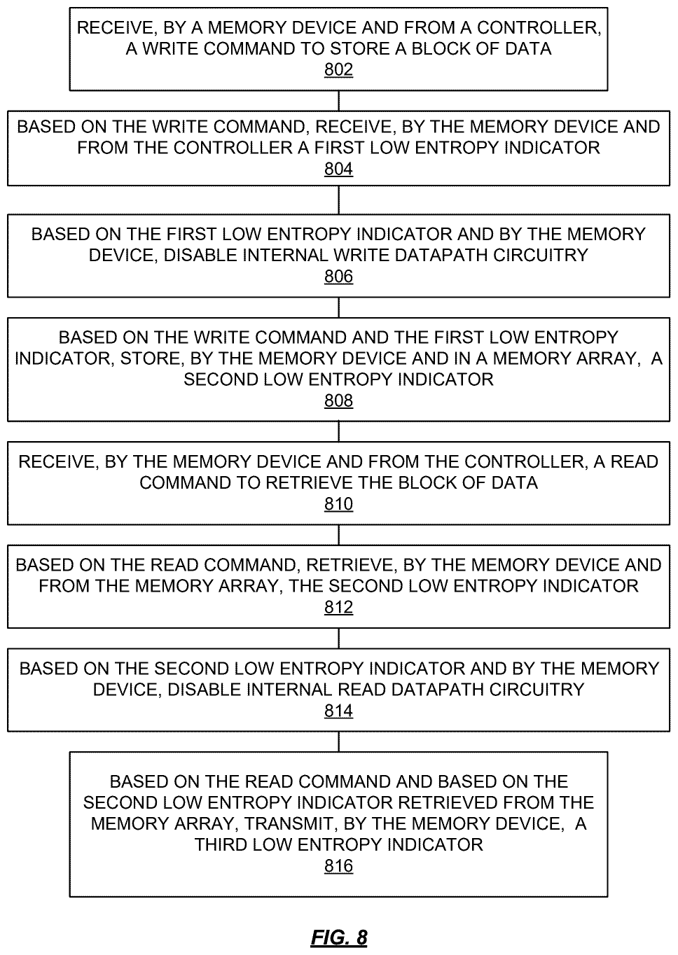

FIG. 8 is a flowchart illustrating a method of operating a memory device storing low entropy data. The steps illustrated in FIG. 8 may be performed by one or more elements of system 100, and/or system 400. By a memory device and from a controller, a write command to store a block of data is received (802). For example, memory device 410 may receive, from controller 420, a write command to store a data burst of data.

Based on the write command, by the memory device, and from the controller, a first low entropy indicator is received (804). For example, memory device 410 may receive, from controller 420, a data strobe pattern (e.g., a one of the LE-DQS pattern illustrated in FIG. 5A or FIG. 5B) that indicates low entropy write data is being indicated. Based on the first low entropy indicator and by the memory device, internal write datapath circuitry is disabled (806). For example, based on the data strobe pattern that indicates low entropy write data is being indicated, memory device 410 may disable DQ write circuitry 414. Based on the write command, the first low entropy indicator, in a memory array, and by the memory device, the block of data is stored in association with a second low entropy indicator (808). For example, based on the write command and based on the data strobe pattern that indicates low entropy write data is being indicated, the write data may be stored by memory device 410 in data memory cells 430 in association with a low entropy indicator in flag memory cells 435.

By a memory device and from a controller, a read command to retrieve a block of data is received (810). For example, memory device 410 may receive, from controller 420, a read command to retrieve from data memory cells 430 a data burst of data. Based on the read command, by the memory device, and from the memory array, the second low entropy indicator is retrieved (812). For example, memory device 410 may, based on the read command, retrieve the low entropy indicator from flag memory cells 435. Based on the second low entropy indicator and by the memory device, internal read datapath circuitry is disabled (814). For example, based on the low entropy indicator retrieved from flag memory cells 435, memory device 410 may disable DQ read circuitry 415.

Based on the read command, the second low entropy indicator retrieved from the memory array, and by the memory device, a third low entropy indicator is transmitted (816). For example, based on the read command and the low entropy indicator retrieved from flag memory cells 435, memory device 410 may transmit a data strobe pattern (e.g., one of the LE-DQS patterns illustrated in FIG. 5A or FIG. 5B) that indicates low entropy data is being indicated.

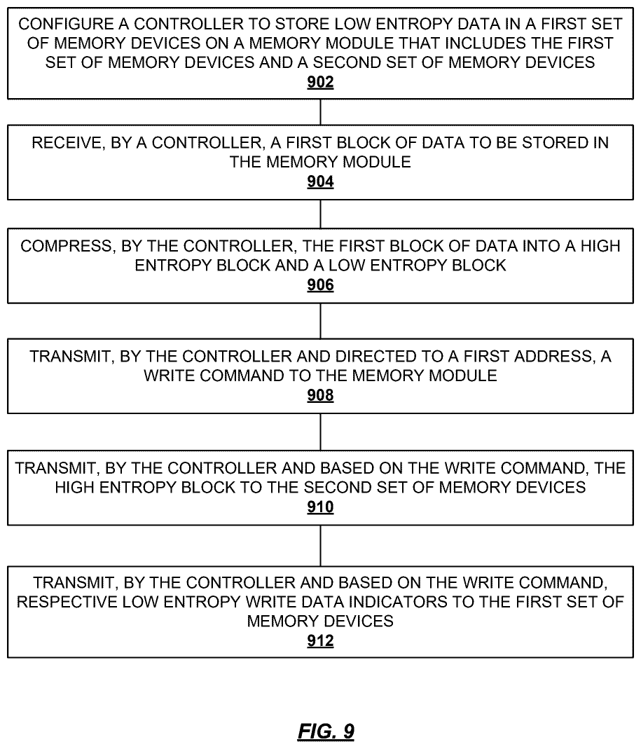

FIG. 9 is a flowchart illustrating a method of operating a controller to write high entropy and low entropy data. The steps illustrated in FIG. 9 may be performed by one or more elements of system 100, and/or system 400. A controller is configured to store low entropy data in a first set of memory devices on a memory module that includes the first set of memory device and a second set of memory devices (902). For example, controller 120 may be configured to store low entropy portion 128l from data CODEC 128 in memory device 111a, memory device 111b, memory device 111h, and memory device 111j. Controller 120 may be configured to store low entropy portion 128l from data CODEC 128 in memory device 111a, memory device 111b, memory device 111h, and memory device 111j and high entropy portion 128h from data CODEC 128 in memory devices memory devices 111c-111g, and memory device 111i based on configuration information from host 130. Controller 120 may be configured to store low entropy portion 128l from data CODEC 128 in memory device 111a, memory device 111b, memory device 111h, and memory device 111j and high entropy portion 128h from data CODEC 128 in memory devices memory devices 111c-111g, and memory device 111i based on respective temperature indicators associated with one or more of memory device 111a-111j. Controller 120 may be configured to store low entropy portion 128l from data CODEC 128 in a variable number of memory device 111a, memory device 111b, memory device 111h, and memory device 111j based on the size of low entropy portion 128l (and/or the size of high entropy portion 128h) from data CODEC 128.

By a controller, a first block of data to be stored in the memory module is received (904). For example, controller 120 may receive, from host 130, a cache line sized data block to be stored in module 110. By the controller, the first block of data is compressed into a high entropy block and a low entropy block (906). For example, controller 120, using data CODEC 128, may compress the data block from host 130 into a high entropy portion 128h and a low entropy portion 128l. By the controller and directed to a first address, a first write command is transmitted to the first set of memory devices and the second set of memory devices (908). For example, controller 120 may transmit, using CA interface 122, a write command, directed to a first address, to memory devices 111a-111j of module 110.

By the controller and based on the first write command, the high entropy block is transmitted to the second set of memory devices (910). For example, controller 120 may transmit, to memory devices 111c-111g, and memory device 111i, the high entropy portion 128h of the compressed data block generated by data CODEC 128. By the controller and based on the first write command, respective low entropy write data indicators are transmitted to the first set of memory devices (912). For example, controller 120 may transmit, to respective ones of memory device 111a, memory device 111b, memory device 111h, and memory device 111j, low entropy write data indicators (e.g., using encoded per memory device data strobe signals).

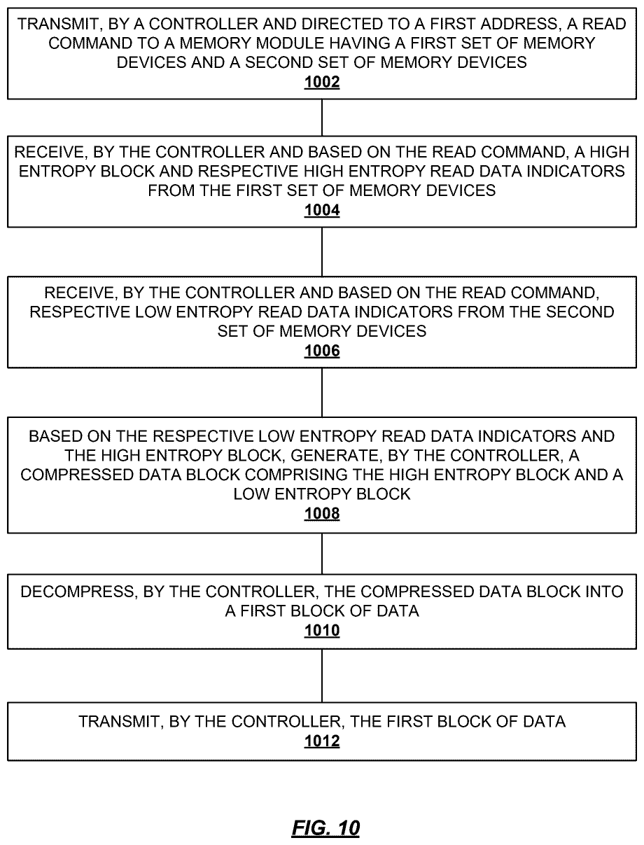

FIG. 10 is a flowchart illustrating a method of operating a controller to read high entropy and low entropy data. The steps illustrated in FIG. 10 may be performed by one or more elements of system 100, and/or system 400. By a controller and directed to a first address, a read command is transmitted to a memory device having a first set of memory devices and a second set of memory devices (1002). For example, controller 120 may transmit, to module 110, a read command directed to a first address where controller 120 has been configured (e.g., by configuration information 127a) to store high entropy data in memory devices 111c-111g, and memory device 111i and to store low entropy data (if present) in memory device 111a, memory device 111b, memory device 111h, and memory device 111j.

By the controller and based on the read command, a high entropy block and respective high entropy read data indicators are received from the first set of memory devices (1004). For example, based on the read command, controller 120 may respectively receive, from memory devices 111c-111g, and memory device 111i, high entropy data in a data burst that is timed by respective data strobe signals from memory devices 111c-111g, and memory device 111i that use the HE-DQS pattern illustrated in FIG. 5A and FIG. 5B.

By the controller and based on the read command, respective low entropy read data indicators are received from the second set of memory devices (1006). For example, based on the read command, controller 120 may respectively receive, from memory device 111a, memory device 111b, memory device 111h, and memory device 111j, respective data strobe signals from memory device 111a, memory device 111b, memory device 111h, and memory device 111j that follows one of the LE-DQS patterns illustrated in FIG. 5A or FIG. 5B.

Based on the respective low entropy read data indicators and the high entropy block, and by the controller, a compressed data block comprising the high entropy block and a low entropy block are generated (1008). For example, based on the data strobe signals from memory device 111a, memory device 111b, memory device 111h, and memory device 111j, and the high entropy data in the respective data bursts from memory devices 111c-111g, and memory device 111i, DQ steering circuitry 129 of controller 120 may generate a compressed data block (e.g., compressed data block 305) having a high entropy portion and a low entropy portion. By the controller, the compressed data block is decompressed into a first block of data (1010). For example, data CODEC 128 may decompress the compressed data into a decompressed block of data (e.g., data block 306). By the controller, the first block of data is transmitted (1012). For example, controller 120 may transmit, via host interface 125 and to host 130, the decompressed block of data.

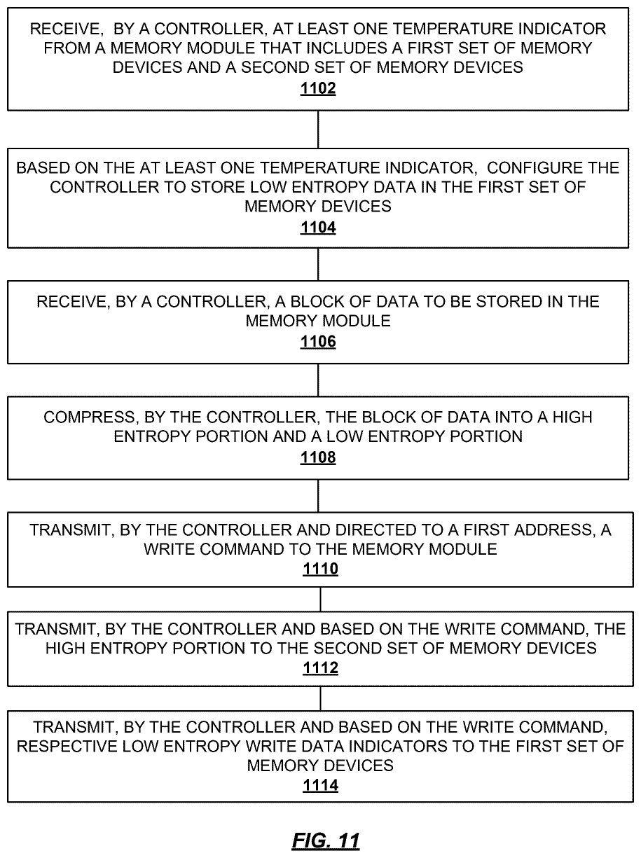

FIG. 11 is a flowchart illustrating a method of operating a controller to locate data based on memory device temperature. The steps illustrated in FIG. 11 may be performed by one or more elements of system 100, and/or system 400. By a controller, at least one temperature indicator is received from a memory module that includes a first set of memory devices and a second set of memory devices (1102). For example, controller 120 may receive, from module 110, one or more temperature indicators associated with respective ones of memory devices 111a-111j.

Based on the at least one temperature indicator, the controller is configured to store low entropy data in the first set of memory devices (1104). For example, controller 120 may be configured to store low entropy portion 128l from data CODEC 128 in memory device 111a, memory device 111b, memory device 111h, and memory device 111j and high entropy portion 128h from data CODEC 128 in memory devices memory devices 111c-111g, and memory device 111i based on one or more respective temperature indicators associated with one or more of memory device 111a-111j.

By a controller, a block of data to be stored in the memory module is received (1106). For example, controller 120 may receive, from host 130, a cache line sized data block to be stored in module 110. By the controller, the block of data is compressed into a high entropy block and a low entropy block (1108). For example, controller 120, using data CODEC 128, may compress the data block from host 130 into a high entropy portion 128h and a low entropy portion 128l. By the controller and directed to a first address, a write command is transmitted to the memory module (1110). For example, controller 120 may transmit, using CA interface 122, a write command, directed to a first address, to memory devices 111a-111j of module 110.

By the controller and based on the write command, the high entropy block is transmitted to the second set of memory devices (1112). For example, controller 120 may transmit, to memory devices 111c-111g, and memory device 111i, the high entropy portion 128h of the compressed data block generated by data CODEC 128. By the controller and based on the write command, respective low entropy write data indicators are transmitted to the first set of memory devices (1114). For example, controller 120 may transmit, to respective ones of memory device 111a, memory device 111b, memory device 111h, and memory device 111j, low entropy write data indicators (e.g., using respective data strobe signals to memory device 111a, memory device 111b, memory device 111h, and memory device 111j that follow one of the LE-DQS patterns illustrated in FIG. 5A or FIG. 5B).

The methods, systems and devices described above may be implemented in computer systems, or stored by computer systems. The methods described above may also be stored on a non-transitory computer readable medium. Devices, circuits, and systems described herein may be implemented using computer-aided design tools available in the art, and embodied by computer-readable files containing software descriptions of such circuits. This includes, but is not limited to one or more elements of memory system 100, and/or system 400, and their components. These software descriptions may be: behavioral, register transfer, logic component, transistor, and layout geometry-level descriptions. Moreover, the software descriptions may be stored on storage media or communicated by carrier waves.

Data formats in which such descriptions may be implemented include, but are not limited to: formats supporting behavioral languages like C, formats supporting register transfer level (RTL) languages like Verilog and VHDL, formats supporting geometry description languages (such as GDSII, GDSIII, GDSIV, CIF, and MEBES), and other suitable formats and languages. Moreover, data transfers of such files on machine-readable media may be done electronically over the diverse media on the Internet or, for example, via email. Note that physical files may be implemented on machine-readable media such as: 4 mm magnetic tape, 8 mm magnetic tape, 3-½ inch floppy media, CDs, DVDs, and so on.

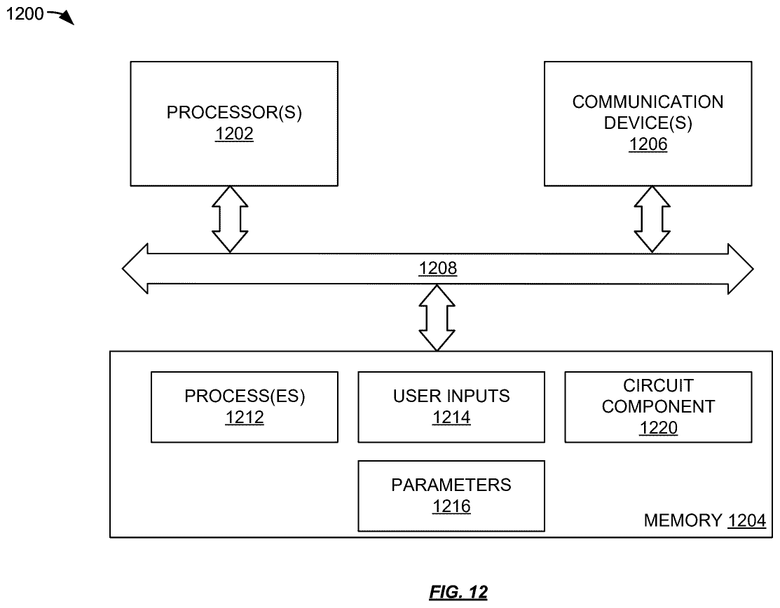

FIG. 12 is a block diagram illustrating one embodiment of a processing system 1200 for including, processing, or generating, a representation of a circuit component 1220. Processing system 1200 includes one or more processors 1202, a memory 1204, and one or more communications devices 1206. Processors 1202, memory 1204, and communications devices 1206 communicate using any suitable type, number, and/or configuration of wired and/or wireless connections 1208.

Processors 1202 execute instructions of one or more processes 1212 stored in a memory 1204 to process and/or generate circuit component 1220 responsive to user inputs 1214 and parameters 1216. Processes 1212 may be any suitable electronic design automation (EDA) tool or portion thereof used to design, simulate, analyze, and/or verify electronic circuitry and/or generate photomasks for electronic circuitry. Representation 1220 includes data that describes all or portions of memory system 100, and/or system 400, and their components, as shown in the Figures.

Representation 1220 may include one or more of behavioral, register transfer, logic component, transistor, and layout geometry-level descriptions. Moreover, representation 1220 may be stored on storage media or communicated by carrier waves.

Data formats in which representation 1220 may be implemented include, but are not limited to: formats supporting behavioral languages like C, formats supporting register transfer level (RTL) languages like Verilog and VHDL, formats supporting geometry description languages (such as GDSII, GDSIII, GDSIV, CIF, and MEBES), and other suitable formats and languages. Moreover, data transfers of such files on machine-readable media may be done electronically over the diverse media on the Internet or, for example, via email.

User inputs 1214 may comprise input parameters from a keyboard, mouse, voice recognition interface, microphone and speakers, graphical display, touch screen, or other type of user interface device. This user interface may be distributed among multiple interface devices. Parameters 1216 may include specifications and/or characteristics that are input to help define representation 1220. For example, parameters 1216 may include information that defines device types (e.g., NFET, PFET, etc.), topology (e.g., block diagrams, circuit descriptions, schematics, etc.), and/or device descriptions (e.g., device properties, device dimensions, power supply voltages, simulation temperatures, simulation models, etc.).

Memory 1204 includes any suitable type, number, and/or configuration of non-transitory computer-readable storage media that stores processes 1212, user inputs 1214, parameters 1216, and circuit component 1220.

Communications devices 1206 include any suitable type, number, and/or configuration of wired and/or wireless devices that transmit information from processing system 1200 to another processing or storage system (not shown) and/or receive information from another processing or storage system (not shown). For example, communications devices 1206 may transmit circuit component 1220 to another system. Communications devices 1206 may receive processes 1212, user inputs 1214, parameters 1216, and/or circuit component 1220 and cause processes 1212, user inputs 1214, parameters 1216, and/or circuit component 1220 to be stored in memory 1204.

Implementations discussed herein include, but are not limited to, the following examples:

Example 1: A controller, comprising: an interface to communicate commands, addresses, data, and timing reference signals with a memory module comprising a plurality of memory devices, the plurality of memory device including a first set of memory devices and a second set of memory devices; compression circuitry to compress a first block of data into a high entropy portion and a low entropy portion; and the interface to transmit, to the plurality of memory devices and directed to a first address, a write command to write the high entropy portion to the first set of memory devices and the low entropy portion to the second set of memory devices, the interface to also transmit, to the first set of memory devices, the high entropy portion, the interface to also transmit, to the second set of memory devices, respective low entropy write indicators.

Example 2: The controller of example 1, further comprising: selection circuitry to determine which of the plurality of memory devices are in the first set of memory devices and the second set of memory devices.

Example 3: The controller of example 1, wherein the second set of memory devices are selected based on at least one temperature indicator associated with the second set of memory devices.

Example 4: The controller of example 1, wherein, based on the low entropy write indicators, the second set of memory devices are to disable internal datapath circuitry during at least during a portion of communication of the high entropy portion to the first set of memory devices.

Example 5: The controller of example 1, wherein, based on the respective low entropy write indicators, each of the second set of memory devices are to store respective low entropy data indicators in association with the first address.

Example 6. The controller of example 5, wherein the interface is to further transmit a read command directed to the first address to read the high entropy portion from the first set of memory devices and the low entropy portion from the second set of memory devices, each of the second set of memory devices to, based on the respective low entropy data indicators stored in association with the first address, provide respective low entropy read indicators to the interface.

Example 7: The controller of example 6, wherein the low entropy write indicators and the low entropy read indicators are communicated using timing reference signals.

Example 8: A memory device, comprising: a memory array; an interface to communicate commands, addresses, data, and timing reference signals with a controller to access the memory array, the interface to receive a low entropy write indicator in association with a write command directed to a first address; and the memory device to, in association with the first address and based on the low entropy write indicator, write a low entropy data indicator to the memory array.

Example 9: The memory device of example 8, wherein the memory device is to, based on the low entropy write indicator, disable internal datapath circuitry during a time for receiving data associated with the write command.

Example 10: The memory device of example 8, wherein the memory device is to transmit, to the controller, an indicator of a temperature associated with the memory device.

Example 11: The memory device of example 8, wherein the memory device is to receive a first read command directed to the first address, the memory device to, based on the low entropy data indicator associated with the first address, transmit a low entropy read indicator via the interface.

Example 12: The memory device of example 8, wherein the interface to receive a high entropy write indicator in association with a second write command directed to a second address, and the memory device is to, in association with the second address and based on the high entropy write indicator, write a high entropy data indicator to the memory array.

Example 13: The memory device of example 12, further comprising: error detection and correction circuitry.

Example 14: The memory device of example 13, wherein the memory device is to receive a second read command directed to the second address, the memory device to, based on the high entropy data indicator associated with the second address, enable the error detection and correction circuitry.

Example 15: A method of operating a memory system, comprising: receiving, by a controller, a first block of data to be stored in a memory module that includes a first set of memory devices and a second set of memory devices; compressing, by the controller, the first block of data into a high entropy block and a low entropy block; transmitting, by the controller and directed to a first address, a first write command to the first set of memory devices and the second set of memory devices; transmitting, by the controller and in association with the first write command, respective portions of the high entropy block and respective high entropy write data indicators to the first set of memory devices; transmitting, by the controller and in association with the first write command, respective low entropy write data indicators to the second set of memory devices; based on the respective high entropy write data indicators, storing, by each of the first set of memory devices and in association with the first address, respective high entropy data indicators; and based on the respective low entropy write data indicators, storing, by each of the second set of memory devices and in association with the first address, respective low entropy data indicators.

Example 16: The method of example 15, further comprising: transmitting, by the controller and directed to the first address, a first read command to the first set of memory devices and the second set of memory devices; receiving, by the controller and in association with the first read command, the high entropy block from the first set of memory devices; and transmitting, by each of the second set of memory devices and in association with the first read command, respective low entropy read data indicators to the controller.

Example 17: The method of example 16, further comprising: based on the respective low entropy read data indicators and the high entropy block received from the first set of memory device, decompressing the high entropy block and the low entropy block into the first block of data.

Example 18: The method of example 17, further comprising: transmitting, by the controller and in association with the first write command, respective high entropy write data indicators to the first set of memory devices.

Example 19: The method of example 18, further comprising: based on the respective high entropy write data indicators, storing, by each of the first set of memory devices and in association with the first address, respective high entropy data indicators.

Example 20: The method of example 19, further comprising: based on the respective high entropy data indicators, calculating, by each of the first set of memory devices, respective error detection and correction information based on respective portions of the high entropy block received by each of the first set of memory devices in association with the first write command.

The foregoing description of the invention has been presented for purposes of illustration and description. It is not intended to be exhaustive or to limit the invention to the precise form disclosed, and other modifications and variations may be possible in light of the above teachings. The embodiment was chosen and described in order to best explain the principles of the invention and its practical application to thereby enable others skilled in the art to best utilize the invention in various embodiments and various modifications as are suited to the particular use contemplated. It is intended that the appended claims be construed to include other alternative embodiments of the invention except insofar as limited by the prior art.

What is claimed is:

1. A controller, comprising:
an interface to communicate commands, addresses, data, and timing reference signals with a memory module comprising a plurality of memory devices, the plurality of memory device including a first set of memory devices and a second set of memory devices;
compression circuitry to compress a first block of data into a high entropy portion and a low entropy portion; and
the interface to transmit, to the plurality of memory devices and directed to a first address, a write command to write the high entropy portion to the first set of memory devices and the low entropy portion to the second set of memory devices, the interface to also transmit, to the first set of memory devices, the high entropy portion, the interface to also transmit, to the second set of memory devices, respective low entropy write indicators.

2. The controller of claim 1, further comprising:
selection circuitry to determine which of the plurality of memory devices are in the first set of memory devices and the second set of memory devices.

3. The controller of claim 1, wherein the second set of memory devices are selected based on at least one temperature indicator associated with the second set of memory devices.

4. The controller of claim 1, wherein, based on the low entropy write indicators, the second set of memory devices are to disable internal datapath circuitry during at least during a portion of communication of the high entropy portion to the first set of memory devices.

5. The controller of claim 1, wherein, based on the respective low entropy write indicators, each of the second set of memory devices are to store respective low entropy data indicators in association with the first address.

6. The controller of claim 5, wherein the interface is to further transmit a read command directed to the first address to read the high entropy portion from the first set of memory devices and the low entropy portion from the second set of memory devices, each of the second set of memory devices to, based on the respective low entropy data indicators stored in association with the first address, provide respective low entropy read indicators to the interface.

7. The controller of claim 6, wherein the low entropy write indicators and the low entropy read indicators are communicated using timing reference signals.

8. A memory device, comprising:
a memory array;
an interface to communicate commands, addresses, data, and timing reference signals with a controller to access the memory array, the interface to receive a low entropy write indicator in association with a write command directed to a first address; and
the memory device to, in association with the first address and based on the low entropy write indicator, write a low entropy data indicator to the memory array.

9. The memory device of claim 8, wherein the memory device is to, based on the low entropy write indicator, disable internal datapath circuitry during a time for receiving data associated with the write command.

10. The memory device of claim 8, wherein the memory device is to transmit, to the controller, an indicator of a temperature associated with the memory device.

11. The memory device of claim 8, wherein the memory device is to receive a first read command directed to the first address, the memory device to, based on the low entropy data indicator associated with the first address, transmit a low entropy read indicator via the interface.

12. The memory device of claim 8, wherein the interface to receive a high entropy write indicator in association with a second write command directed to a second address, and the memory device is to, in association with the second address and based on the high entropy write indicator, write a high entropy data indicator to the memory array.

13. The memory device of claim 12, further comprising:
error detection and correction circuitry.

14. The memory device of claim 13, wherein the memory device is to receive a second read command directed to the second address, the memory device to, based on the high entropy data indicator associated with the second address, enable the error detection and correction circuitry.

15. A method of operating a memory system, comprising:
receiving, by a controller, a first block of data to be stored in a memory module that includes a first set of memory devices and a second set of memory devices;
compressing, by the controller, the first block of data into a high entropy block and a low entropy block;
transmitting, by the controller and directed to a first address, a first write command to the first set of memory devices and the second set of memory devices;
transmitting, by the controller and in association with the first write command, respective portions of the high entropy block and respective high entropy write data indicators to the first set of memory devices;
transmitting, by the controller and in association with the first write command, respective low entropy write data indicators to the second set of memory devices;
based on the respective high entropy write data indicators, storing, by each of the first set of memory devices and in association with the first address, respective high entropy data indicators; and
based on the respective low entropy write data indicators, storing, by each of the second set of memory devices and in association with the first address, respective low entropy data indicators.

16. The method of claim 15, further comprising:
transmitting, by the controller and directed to the first address, a first read command to the first set of memory devices and the second set of memory devices;
receiving, by the controller and in association with the first read command, the high entropy block from the first set of memory devices; and
transmitting, by each of the second set of memory devices and in association with the first read command, respective low entropy read data indicators to the controller.

17. The method of claim 16, further comprising:
based on the respective low entropy read data indicators and the high entropy block received from the first set of memory device, decompressing the high entropy block and the low entropy block into the first block of data.

18. The method of claim 17, further comprising:
transmitting, by the controller and in association with the first write command, respective high entropy write data indicators to the first set of memory devices.

19. The method of claim 18, further comprising:
based on the respective high entropy write data indicators, storing, by each of the first set of memory devices and in association with the first address, respective high entropy data indicators.

20. The method of claim 19, further comprising:
based on the respective high entropy data indicators, calculating, by each of the first set of memory devices, respective error detection and correction information based on respective portions of the high entropy block received by each of the first set of memory devices in association with the first write command.
